(19) United States
(12) Patent Application Publication
(10) Pub. No.: US 2026/0367322 A1
(43) Pub. Date: Nov. 19, 2026

(54) SEMICONDUCTOR PHOTONICS DEVICES AND METHODS OF FORMATION

(71) Applicant: Taiwan Semiconductor Manufacturing Company, Ltd., Hsinchu (TW)

(72) Inventors: Chih-Tsung SHIH, Hsinchu City (TW); Wei-kang LIU, Taichung City (TW); Hau-Yan LU, Hsinchu City (TW); Chi-Yuan SHIH, Hsinchu (TW); Ming-Fa CHEN, Taichung City (TW); YingKit Felix TSUI, Cupertino, CA (US)

(21) Appl. No.: 19/755,426

(22) Filed: Jul. 27, 2026

Related U.S. Application Data
(62) Division of application No. 18/475,128, filed on Sep. 26, 2023.

(51) Int. Cl. G02B 6/124; G02B 1/11; H10F 77/30; H10F 77/40

(52) U.S. Cl. CPC G02B 6/124; G02B 1/11; H10F 77/331; H10F 77/413

(57) ABSTRACT

A semiconductor photonics device includes a plurality of grating couplers, each configured to couple a particular wavelength (or wavelength range) of an optical signal to a waveguide of the semiconductor photonics device. In some implementations, various implementations of optical signal splitters or filters described herein enable respective wavelengths (or respective wavelength ranges) to be passed to each of the grating couplers (while filtering out other wavelengths or other wavelength ranges), thereby enabling the grating couplers to each handle a respective wavelength (or respective wavelength range). This enables multiple wavelengths (or multiple wavelength ranges) to be distributed across multiple grating couplers, which may increase the bandwidth of the semiconductor photonics device relative to a semiconductor photonics device that includes only a single grating coupler.

### RELATED APPLICATION

This application is a divisional of U.S. patent application Ser. No. 18/475,128, filed Sep. 26, 2023, which is incorporated herein by reference in its entirety.

### BACKGROUND

In semiconductor photonics, semiconductor materials such as silicon are used as an optical transmission medium. For example, a semiconductor photonics device may be used for optical communications, and may include coupling systems that convert between electrical signals and optical signals. Additionally, some semiconductor photonics devices may include integrated electronic components on a same semiconductor substrate for processing transmitted or received optical signals.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example environment in which systems and/or methods described herein may be implemented.

FIGS. 2A-2F are diagrams of an example semiconductor photonics device described herein.

FIGS. 3A-3H are diagrams of an example implementation of forming a first semiconductor die described herein.

FIGS. 4A-4J are diagrams of an example implementation of forming a second semiconductor die described herein.

FIGS. 5A-5F are diagrams of an example implementation of forming the semiconductor photonics device described herein.

FIGS. 6A-6C are diagrams of an example semiconductor photonics device described herein.

FIGS. 7A-7E are diagrams of an example implementation of forming a second semiconductor die described herein.

FIGS. 8A-8C are diagrams of an example semiconductor photonics device described herein.

FIGS. 9A-9D are diagrams of an example implementation of forming a second semiconductor die described herein.

FIGS. 10A-10C are diagrams of an example semiconductor photonics device described herein.

FIGS. 11A-11E are diagrams of an example implementation of forming a second semiconductor die described herein.

FIG. 12 is a diagram of example components of a device described herein.

FIG. 13 is a flowchart of an example process associated with forming a semiconductor photonics device described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some cases, a semiconductor photonics device may include a grating coupler, an optical transceiver, and a waveguide that couples the grating coupler and the optical transceiver. The grating coupler may be configured to direct an optical signal (e.g., a laser signal or incident light) to and/or from the waveguide. The detector may convert the optical signal to an electrical signal (e.g., when the optical signal is received by the semiconductor photonics device) and/or may convert an electrical signal to the optical signal (e.g., when the optical signal is transmitted by the semiconductor photonics device).

In high-bandwidth optical communications, data may be multiplexed onto different wavelengths of an optical signal. This enables a greater amount of data to be transmitted on the optical signal as compared to a single-frequency optical signal, which enables higher bandwidth optical communications to be realized. However, the bandwidth of a semiconductor photonics device may be limited by one or more components of the semiconductor photonics device. For example, the grating coupler of the semiconductor photonics device may only be capable of handling a limited bandwidth due to data being multiplexed onto different wavelengths of an optical signal.

In some implementations described herein, a semiconductor photonics device includes a plurality of grating couplers, each configured to couple a particular wavelength (or wavelength range) of an optical signal to a waveguide of the semiconductor photonics device. In some implementations, various implementations of optical signal splitters or filters described herein enable respective wavelengths (or respective wavelength ranges) to be passed to each of the grating couplers (while filtering out other wavelengths or other wavelength ranges), thereby enabling the grating couplers to each handle a respective wavelength (or respective wavelength range). This enables multiple wavelengths (or multiple wavelength ranges) to be distributed across multiple grating couplers, which may increase the bandwidth of the semiconductor photonics device relative to a semiconductor photonics device that includes only a single grating coupler.

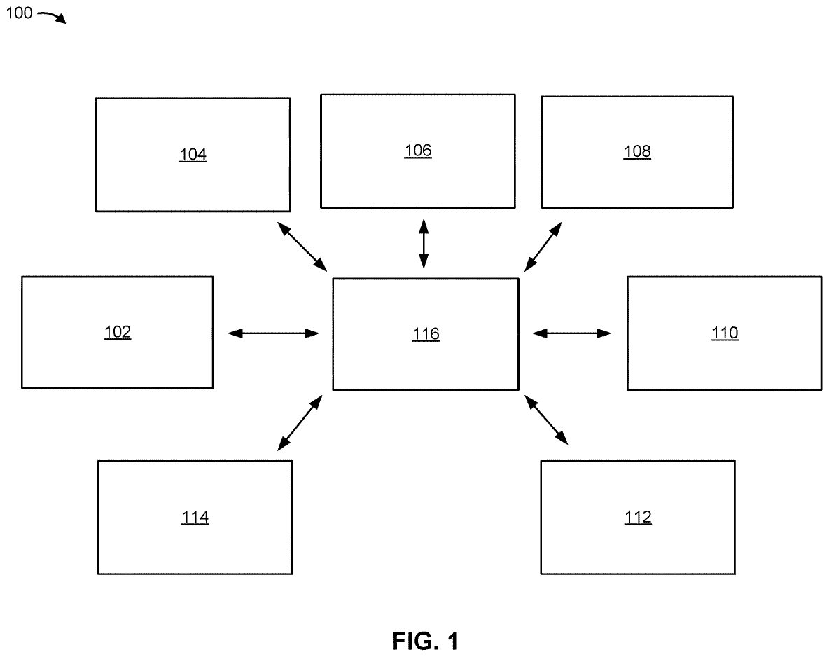

FIG. 1 is a diagram of an example environment 100 in which systems and/or methods described herein may be implemented. As shown in FIG. 1, environment 100 may include a plurality of semiconductor processing tools 102-114 and a wafer/die transport tool 116. The plurality of semiconductor processing tools 102-114 may include a deposition tool 102, an exposure tool 104, a developer tool 106, an etch tool 108, a planarization tool 110, a plating tool 112, an ion implantation tool 114, and/or another type of semiconductor processing tool. The tools included in example environment 100 may be included in a semiconductor clean room, a semiconductor foundry, a semiconductor processing facility, and/or a semiconductor manufacturing facility, among other examples.

The deposition tool 102 is a semiconductor processing tool that includes a semiconductor processing chamber and one or more devices capable of depositing various types of materials onto a substrate. In some implementations, the deposition tool 102 includes a spin coating tool that is capable of depositing a photoresist layer on a substrate such as a wafer. In some implementations, the deposition tool 102 includes a chemical vapor deposition (CVD) tool such as a plasma enhanced CVD (PECVD) tool, a low-pressure CVD (LPCVD) tool, a high-density plasma CVD (HDP-CVD) tool, a sub-atmospheric CVD (SACVD) tool, an atomic layer deposition (ALD) tool, a plasma-enhanced atomic layer deposition (PEALD) tool, or another type of CVD tool. In some implementations, the deposition tool 102 includes a physical vapor deposition (PVD) tool, such as a sputtering tool or another type of PVD tool. In some implementations, the example environment 100 includes a plurality of different types of deposition tools 102. “Deposition tool 102,” as used herein, may refer to one or more deposition tools 102, one or more of the same type of deposition tools 102, and/or one or more different types of deposition tools 102, among other examples.

The exposure tool 104 is a semiconductor processing tool that is capable of exposing a photoresist layer to a radiation source, such as an ultraviolet light (UV) source (e.g., a deep UV light source, an extreme UV light (EUV) source, and/or the like), an x-ray source, an electron beam (e-beam) source, and/or the like. The exposure tool 104 may expose a photoresist layer to the radiation source to transfer a pattern from a photomask to the photoresist layer. The pattern may include one or more semiconductor device layer patterns for forming one or more semiconductor devices, may include a pattern for forming one or more structures of a semiconductor device, may include a pattern for etching various portions of a semiconductor device, and/or the like. In some implementations, the exposure tool 104 includes a scanner, a stepper, or a similar type of exposure tool.

The developer tool 106 is a semiconductor processing tool that is capable of developing a photoresist layer that has been exposed to a radiation source to develop a pattern transferred to the photoresist layer from the exposure tool 104. In some implementations, the developer tool 106 develops a pattern by removing unexposed portions of a photoresist layer. In some implementations, the developer tool 106 develops a pattern by removing exposed portions of a photoresist layer. In some implementations, the developer tool 106 develops a pattern by dissolving exposed or unexposed portions of a photoresist layer through the use of a chemical developer.

The etch tool 108 is a semiconductor processing tool that is capable of etching various types of materials of a substrate, wafer, or semiconductor device. For example, the etch tool 108 may include a wet etch tool, a dry etch tool, and/or the like. In some implementations, the etch tool 108 includes a chamber that is filled with an etchant, and the substrate is placed in the chamber for a particular time period to remove particular amounts of one or more portions of the substrate. In some implementations, the etch tool 108 may etch one or more portions of the substrate using a plasma etch or a plasma-assisted etch, which may involve using an ionized gas to isotropically or directionally etch the one or more portions.

The planarization tool 110 is a semiconductor processing tool that is capable of polishing or planarizing various layers of a wafer or semiconductor device. For example, a planarization tool 110 may include a chemical mechanical planarization (CMP) tool and/or another type of planarization tool that polishes or planarizes a layer or surface of deposited or plated material. The planarization tool 110 may polish or planarize a surface of a semiconductor device with a combination of chemical and mechanical forces (e.g., chemical etching and free abrasive polishing). The planarization tool 110 may utilize an abrasive and corrosive chemical slurry in conjunction with a polishing pad and retaining ring (e.g., typically of a greater diameter than the semiconductor device). The polishing pad and the semiconductor device may be pressed together by a dynamic polishing head and held in place by the retaining ring. The dynamic polishing head may rotate with different axes of rotation to remove material and even out any irregular topography of the semiconductor device, making the semiconductor device ﬂat or planar.

The plating tool 112 is a semiconductor processing tool that is capable of plating a substrate (e.g., a wafer, a semiconductor device, and/or the like) or a portion thereof with one or more metals. For example, the plating tool 112 may include a copper electroplating device, an aluminum electroplating device, a nickel electroplating device, a tin electroplating device, a compound material or alloy (e.g., tin-silver, tin-lead, and/or the like) electroplating device, and/or an electroplating device for one or more other types of conductive materials, metals, and/or similar types of materials.

The ion implantation tool 114 is a semiconductor processing tool that is capable of implanting ions into a substrate. The ion implantation tool 114 may generate ions in an arc chamber from a source material such as a gas or a solid. The source material may be provided into the arc chamber, and an arc voltage is discharged between a cathode and an electrode to produce a plasma containing ions of the source material. One or more extraction electrodes may be used to extract the ions from the plasma in the arc chamber and accelerate the ions to form an ion beam. The ion beam may be directed toward the substrate such that the ions are implanted below the surface of the substrate.

The wafer/die transport tool 116 may be included in a cluster tool or another type of tool that includes a plurality of processing chambers, and may be configured to transport substrates and/or semiconductor devices between the plurality of processing chambers, to transport substrates and/or semiconductor devices between a processing chamber and a buffer area, to transport substrates and/or semiconductor devices between a processing chamber and an interface tool such as an equipment front end module (EFEM), and/or to transport substrates and/or semiconductor devices between a processing chamber and a transport carrier (e.g., a front opening unified pod (FOUP)), among other examples. In some implementations, a wafer/die transport tool 116 may be included in a multi-chamber (or cluster) deposition tool 102, which may include a pre-clean processing chamber (e.g., for cleaning or removing oxides, oxidation, and/or other types of contamination or byproducts from a substrate and/or semiconductor device) and a plurality of types of deposition processing chambers (e.g., processing chambers for depositing different types of materials, processing chambers for performing different types of deposition operations).

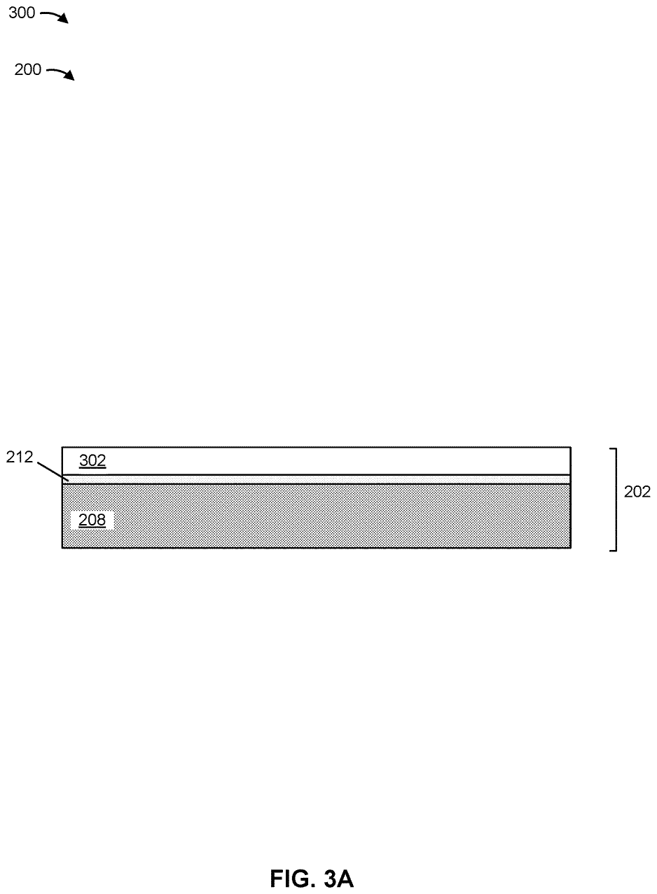

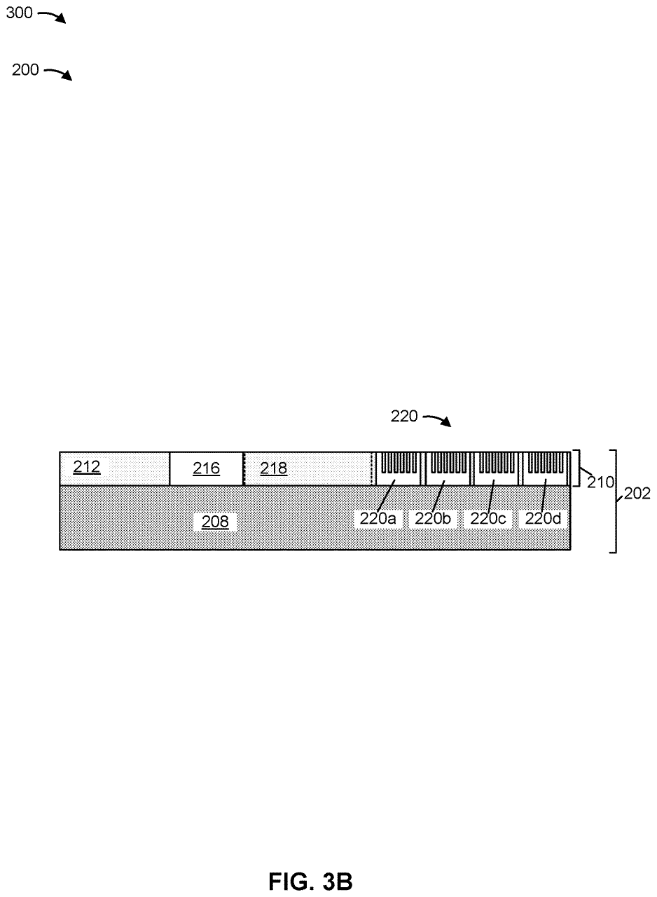

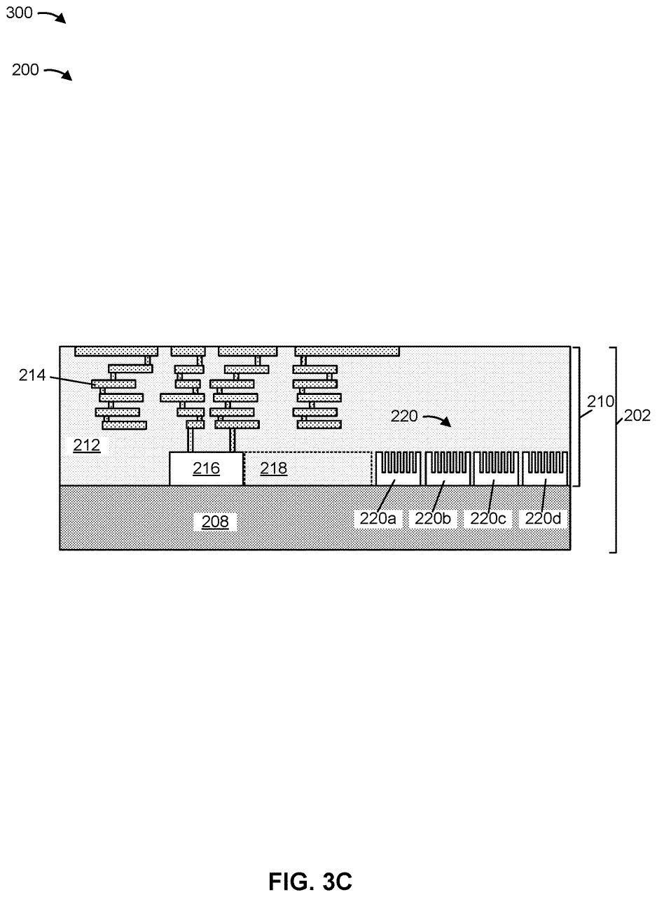

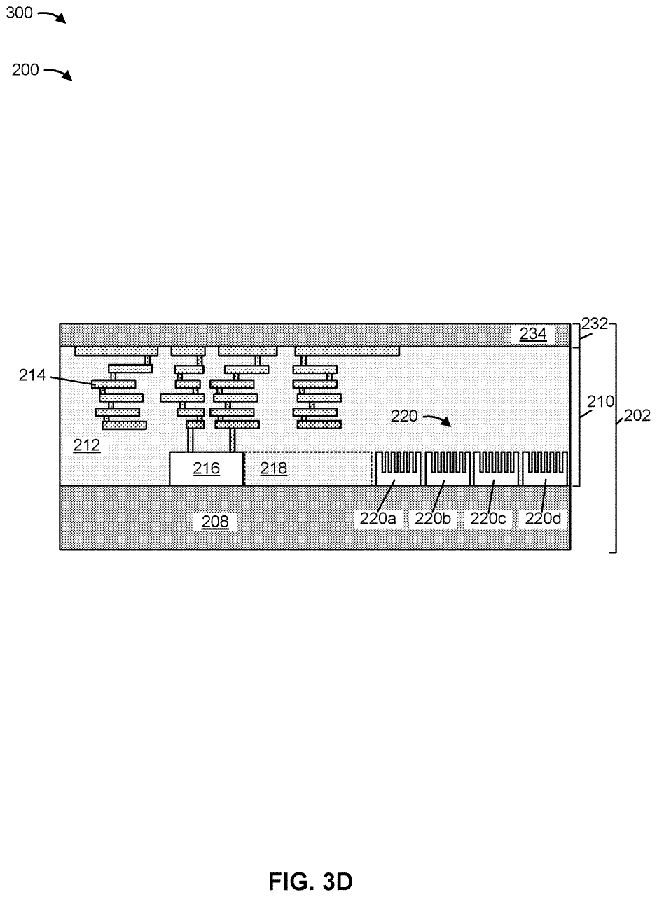

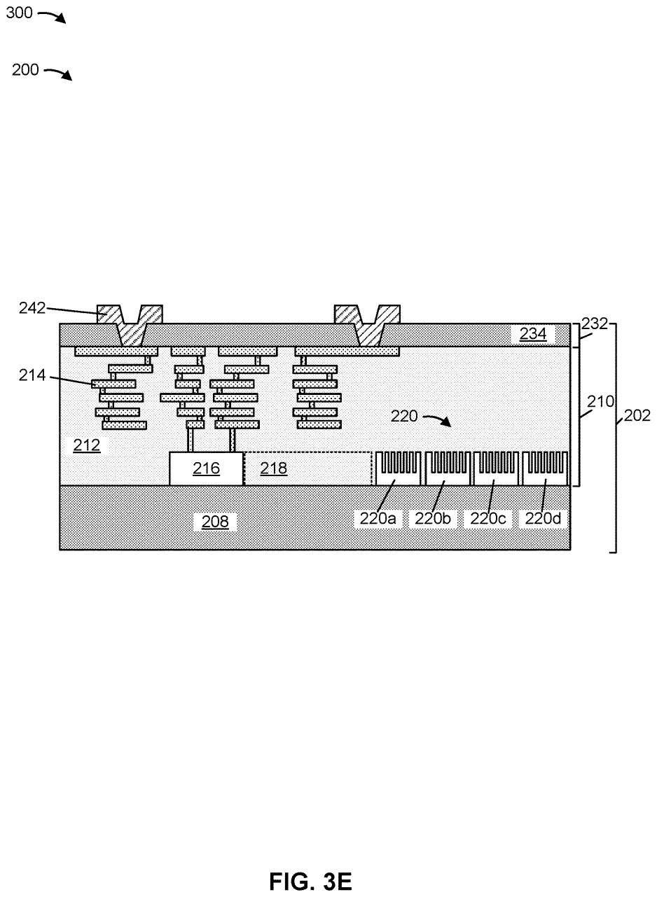

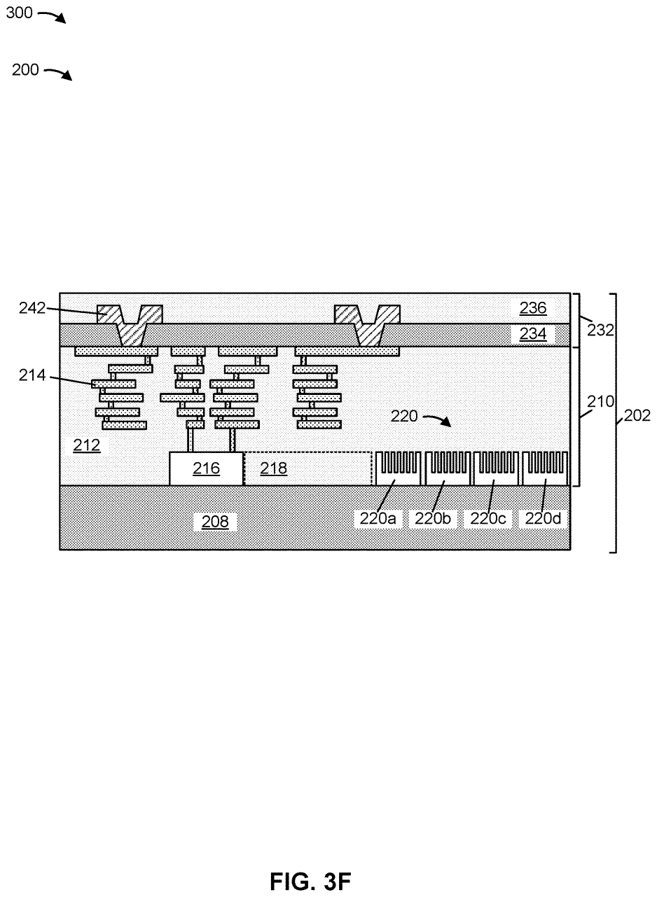

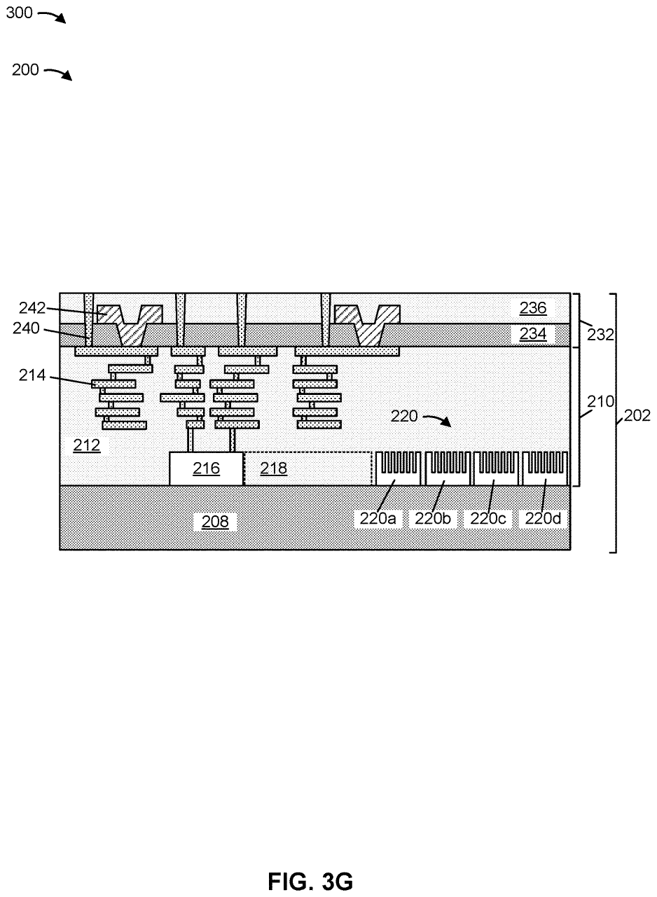

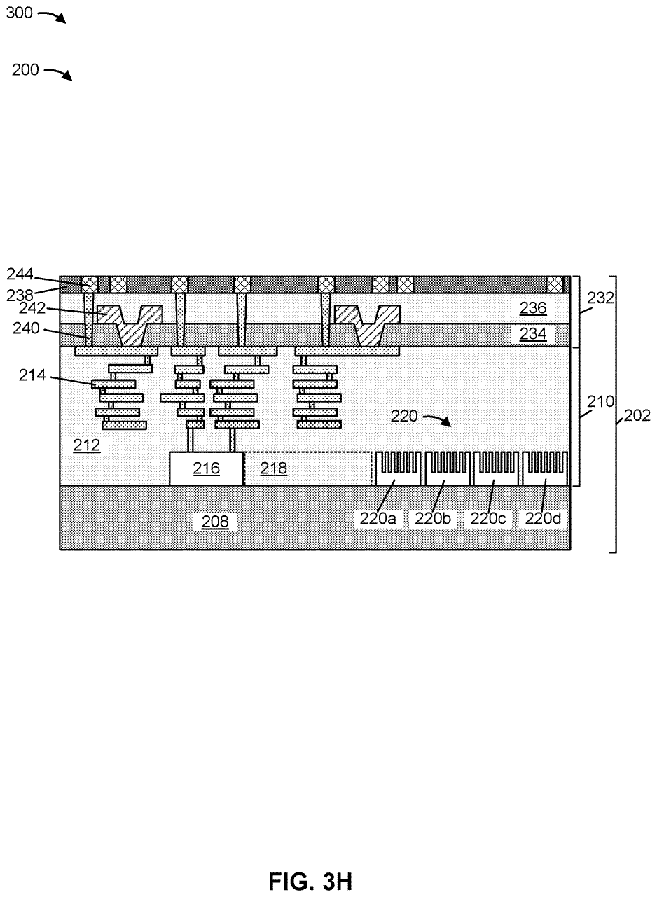

In some implementations, one or more of the semiconductor processing tools 102-114 may perform one or more semiconductor processing operations described herein. For example, one or more of the semiconductor processing tools 102-114 may form, in a first semiconductor die, an optical transceiver, a waveguide coupled with the optical transceiver, and a plurality of grating couplers coupled with the waveguide. As another example, one or more of the semiconductor processing tools 102-114 may form, in a second semiconductor die, one or more anti-reflective coating (ARC) layers. As another example, one or more of the semiconductor processing tools 102-114 may bond the first semiconductor die and the second semiconductor die to form a semiconductor photonics device, wherein the one or more ARC layers are located over at least a subset of the plurality of grating couplers after the first semiconductor die and the second semiconductor die are bonded. As another example, one or more of the semiconductor processing tools 102-114 may form, after bonding the first semiconductor die and the second semiconductor die, one or more micro lenses above the one or more ARC layers. One or more of the semiconductor processing tools 102-114 may perform other semiconductor processing operations described herein, such as in connection with FIGS. 3A-3G, 4A-4J, 5A-5F, 7A-7E, 9A-9D, 11A-11E, and/or 13, among other examples.

The number and arrangement of devices shown in FIG. 1 are provided as one or more examples. In practice, there may be additional devices, fewer devices, different devices, or differently arranged devices than those shown in FIG. 1. Furthermore, two or more devices shown in FIG. 1 may be implemented within a single device, or a single device shown in FIG. 1 may be implemented as multiple, distributed devices. Additionally, or alternatively, a set of devices (e.g., one or more devices) of the example environment 100 may perform one or more functions described as being performed by another set of devices of the example environment 100.

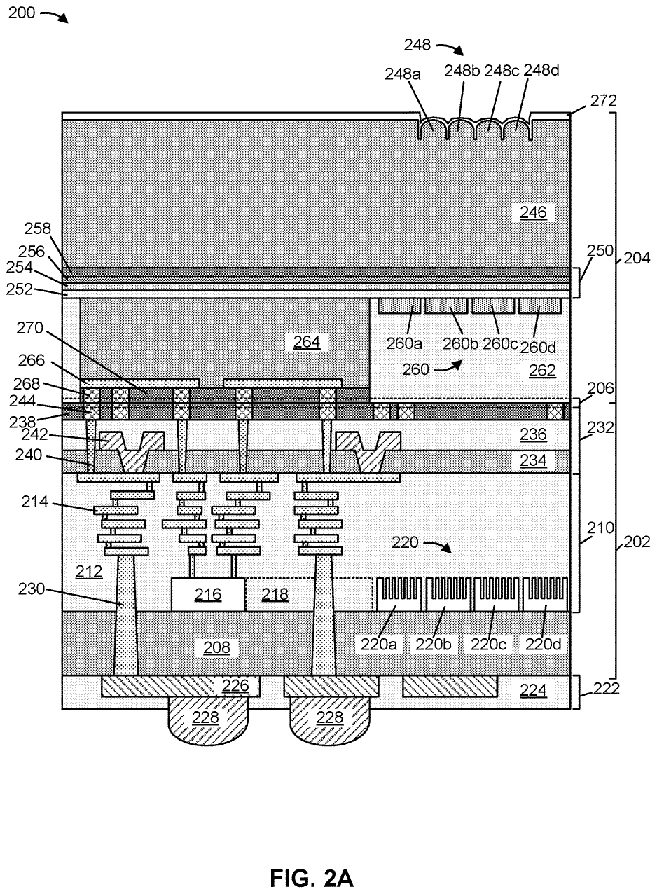

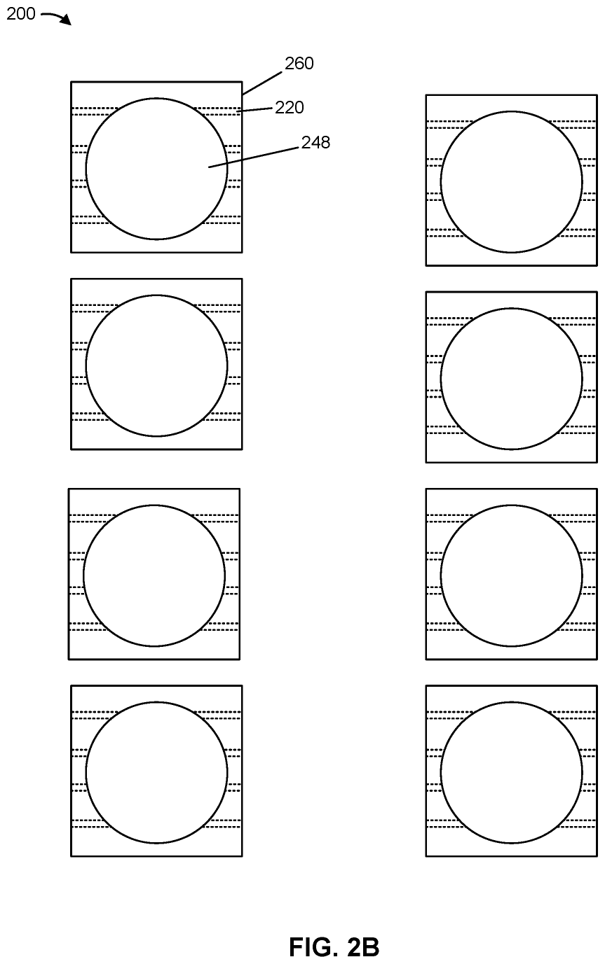

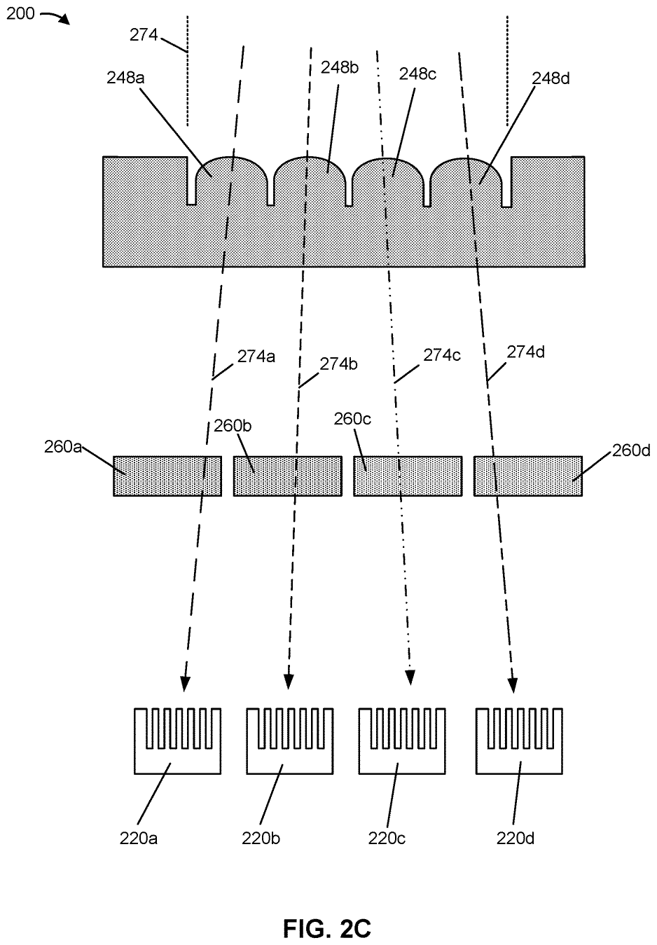

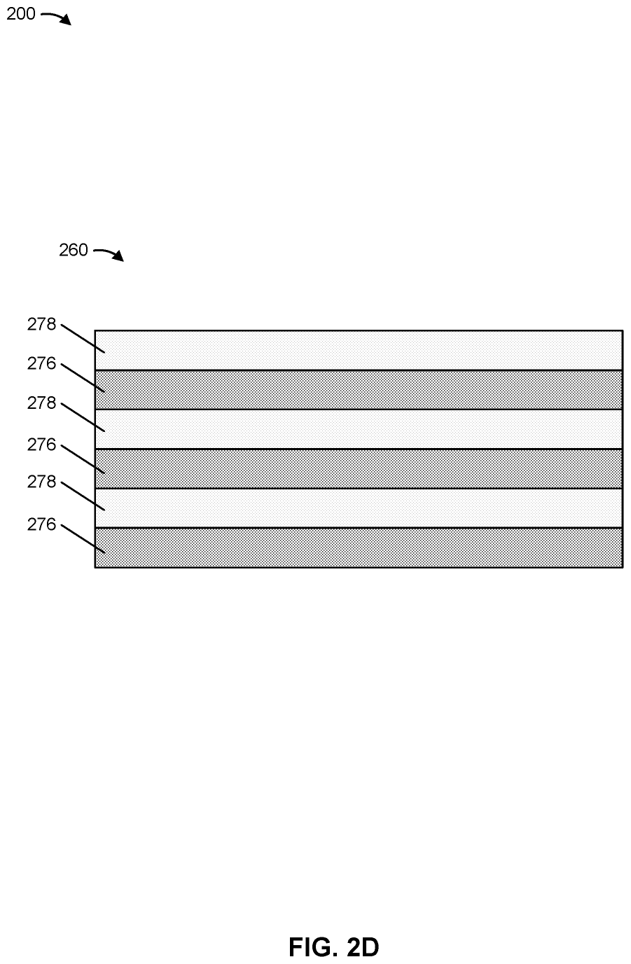

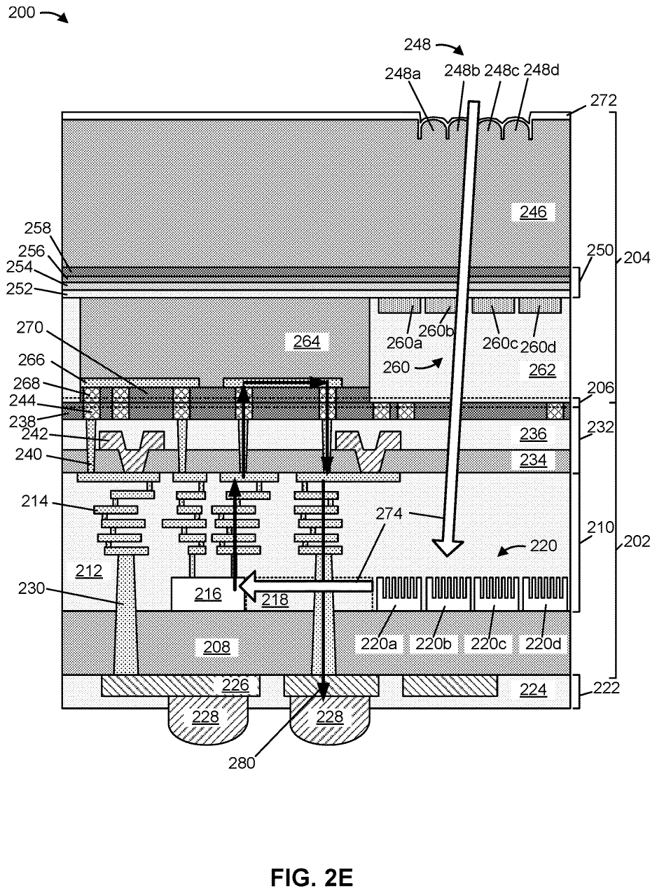

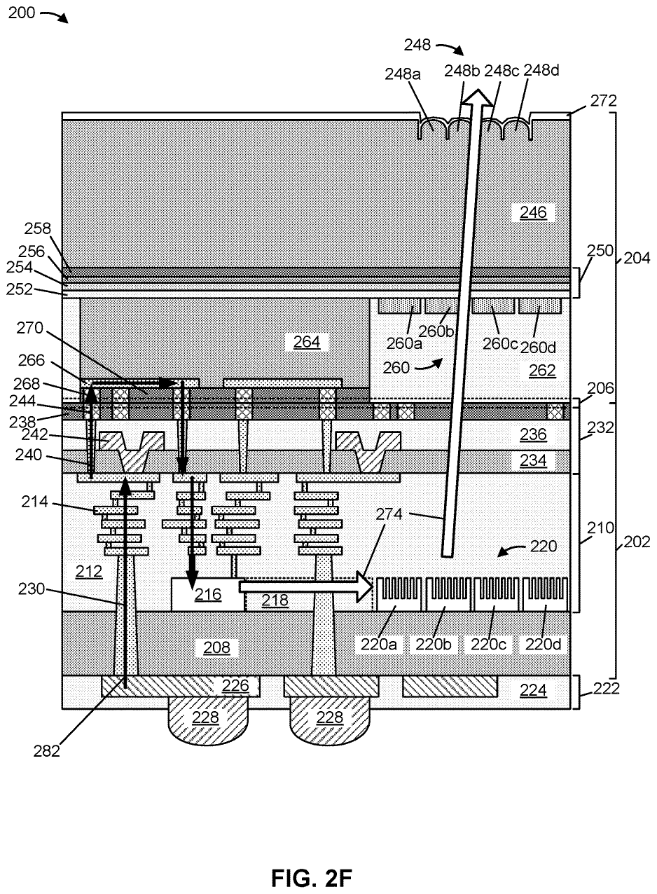

FIGS. 2A-2F are diagrams of an example semiconductor photonics device 200 described herein. The semiconductor photonics device 200 may include a photonics integrated circuit (PIC), such as an optical coupling circuit. In general, the semiconductor photonics device 200 may be configured to convert between electrical signals and optical signals for high-bandwidth optical communications.

FIG. 2A illustrates a cross-sectional view of the semiconductor photonics device 200. As shown in FIG. 2A, the semiconductor photonics device 200 may include a first semiconductor die 202 and a second semiconductor die 204. The semiconductor dies 202 and 204 may each include one or more dies or chiplets, one or more die packages, and/or the like. The first semiconductor die 202 and the second semiconductor die 204 may be bonded at a bonding interface 206. In this way, the first semiconductor die 202 and the second semiconductor die 204 may be stacked or vertically arranged in the semiconductor photonics device 200.

The first semiconductor die 202 may include a semiconductor substrate 208 and a device region 210 above the semiconductor substrate 208. The semiconductor substrate 208 may include a silicon (Si) substrate and/or another type of semiconductor substrate. The device region 210 may include a dielectric layer 212 and a plurality of metallization layers 214 in the dielectric layer 212. The dielectric layer 212 may include one or more dielectric materials, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material.

The metallization layers 214 may provide a signal path for propagation of electrical signals in the first semiconductor die 202 and/or between the first semiconductor die 202 and the second semiconductor die 204. The metallization layers 214 may include may each include vias, trenches, contact plugs, conductive pads, conductive pillars, and/or another type of metallization layers. The metallization layers 214 may include tungsten (W), titanium (Ti), copper (Cu), ruthenium (Ru), cobalt (Co), and/or another electrically conductive material. In some implementations, one or more liners are included around the metallization layers 214, such as adhesion layers, barrier layers, and/or another type of liners.

The device region 210 of the first semiconductor die 202 may further include an optical transceiver 216, a waveguide 218 coupled with the optical transceiver 216, and a plurality of grating couplers 220 (e.g., grating couplers 220a-220d) coupled with the waveguide 218. The optical transceiver 216 may be coupled with one or more metallization layers 214 to enable electrical signals to be provided to and/or from the optical transceiver 216. The optical transceiver 216 may include a photodetector, a photodiode, an optical modulator, and/or another type of semiconductor device that is configured to convert electrical signals to optical signals and/or to convert optical signals to electrical signals.

The waveguide 218 may include a device that is configured to confine optical signals and to permit propagation of optical signals between the optical transceiver 216 and the grating couplers 220. In some implementations, the waveguide 218 includes a semiconductor waveguide, such as a silicon waveguide. In some implementations, the waveguide 218 includes a dielectric waveguide.

The grating couplers 220 may include semiconductor structures (e.g., silicon (Si) structures and/or other types of semiconductor structures) that are configured to direct optical signals to and/or from the waveguide 218. In particular, grating couplers 220 are configured to diffract an optical signal from an off-plane direction to an in-plane direction that is in the plane of the waveguide 218 (e.g., for reception of the optical signal). Additionally and/or alternatively, a grating coupler 220 may be configured to diffract an optical signal from the in-plane direction to an off-plane direction (e.g., for transmission of the optical signal).

Each grating coupler 220 may include a plurality of periodic gratings. The periodicity of the periodic gratings may be selected to achieve diffraction of a particular wavelength or wavelength range of an optical signal. For example, the periodicity of the periodic gratings of the grating coupler 220a may be selected to achieve diffraction of a first wavelength or a first wavelength range of an optical signal, the periodicity of the periodic gratings of the grating coupler 220b may be selected to achieve diffraction of a second wavelength or a second wavelength range of the optical signal, and so on. The wavelength ranges may be non-overlapping wavelength ranges and/or partially-overlapping wavelength ranges. This enables each of the grating couplers 220a-220d to handle a respective wavelength or a respective wavelength range, which enables the bandwidth of the optical signal to be distributed across the grating couplers 220a-220d as opposed to being handled by a single grating coupler. This enables the semiconductor photonics device 200 to process higher bandwidth signals than a semiconductor photonics device that includes only a single grating coupler. Each wavelength or wavelength range may carry multiplexed data transmitted in the optical signal. For example, a first data stream may be transmitted on the first wavelength or the first wavelength range, a second data stream may be transmitted on the second wavelength or the second wavelength range, and so on. The quantity of grating couplers 220a-220d illustrated in FIG. 2A is an example, and other quantities of grating couplers 220 are within the scope of the present disclosure.

As further shown in FIG. 2A, a redistribution layer (RDL) 222 may be included under the semiconductor substrate 208. The RDL 222 may include an electrically insulating layer 224, and one or more metallization layers 226 included in the electrically insulating layer 224 may include a polymer material such as polybenzoxazole (PBO), a polyimide, a low temperature polyimide (LTPI), an epoxy resin, an acrylic resin, a phenol resin, and/or benzocyclobutene (BCB), among other examples. Additionally and/or alternatively, the electrically insulating layer 224 may include a dielectric material, such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material. The metallization layers 226 may each include vias, trenches, contact plugs, conductive pads, conductive pillars, and/or another type of metallization layers. The metallization layers 214 may include aluminum (Al), tungsten (W), titanium (Ti), copper (Cu), ruthenium (Ru), cobalt (Co), and/or another electrically conductive material.

The metallization layers 226 may be electrically coupled and/or physically coupled with conductive pads 228 under the RDL 222. The conductive pads 228 may include conductive terminals, conductive pads, conductive pillars, under bump metallization (UBM) structures, controlled collapse chip connection (C4) bumps, ball grid array (BGA) balls, and/or another type of contacts that enable the semiconductor photonics device 200 to be connected to and/or mounted on another structure such as a semiconductor device package. The conductive pads 228 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The metallization layers 226 may further be electrically coupled and/or physically coupled with the metallization layers 214 by connection structures 230 that extend through the semiconductor substrate 208 and into the dielectric layer 212 of the device region 210. The connection structures 230 may include through silicon vias (TSVs), through package vias (TPVs), through dielectric vias (TDVs), and/or other types of connection structures. The connection structures 230 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The first semiconductor die 202 may further include a die connection region 232 above the device region 210. The die connection region 232 includes a region of the first semiconductor die 202 that is interfaced with the second semiconductor die 204, and may include dielectric layers 234, 236, and 238, among other examples. The dielectric layers 234, 236, and 238 may each include a dielectric material (e.g., the same dielectric material and/or different dielectric materials), such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material. The dielectric layer 234 may be included over and/or on the dielectric layer 212, the dielectric layer 236 may be included over and/or on the dielectric layer 234, and the dielectric layer 238 may be included over and/or on the dielectric layer 236.

Connection structures 240 may extend through the dielectric layers 234 and 236, and may extend between the device region 210 and the dielectric layer 238. Moreover, contacts 242 may be included in the dielectric layers 234 and 236. The connection structures 240 and the contacts 242 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

The connection structures 240 may electrically couple the metallization layers 214 with bonding pads 244 in the dielectric layer 238. The bonding pads 244 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials.

As further shown in FIG. 2A, the second semiconductor die 204 may include a semiconductor substrate 246 such as a silicon (Si) substrate, among other examples. A plurality of micro lenses 248, such as micro lenses 248a-248d, may be formed in a top surface of the semiconductor substrate 246. The micro lenses 248 may be configured to receive an optical signal from, and/or to provide an optical signal to, an external fiberoptic cable and/or another type of optical transmission medium.

Each micro lens 248a-248d may include one or more properties that are selected to achieve transmission of a particular wavelength or wavelength range of the optical signal. In this way, the properties of the micro lenses 248a-248d may be selected to split the optical signal into different wavelengths or different wavelength ranges that are then passed to respective grating couplers 220a-220d. For example, the properties of the micro lens 248a may be selected to achieve transmission of a first wavelength or a first wavelength range of the optical signal to the grating coupler 220a, the properties of the one or more layers of the micro lens 248b may be selected to achieve transmission of a second wavelength or a second wavelength range of the optical signal to the grating coupler 220b, and so on. This enables each of the grating couplers 220a-220d to handle a respective wavelength or a respective wavelength range, which enables the bandwidth of the optical signal to be distributed across the grating couplers 220a-220d, as opposed to being handled by a single grating coupler. This enables the semiconductor photonics device 200 to process higher bandwidth signals than a semiconductor photonics device that includes only a single grating coupler.

The properties of the micro lenses 248a-248d may include the widths of the micro lenses 248a-248d, the heights or thicknesses of the micro lenses 248a-248d, and/or the curvatures of the micro lenses 248a-248d, among other examples. For example, the micro lens 248a may have a first width, the micro lens 248b may have a second width, and so on, where the widths are different widths. As another example, the micro lens 248a may have a first thickness, the micro lens 248b may have a second thickness, and so on, where the thicknesses are different thicknesses. As another example, the micro lens 248a may have a first curvature, the micro lens 248b may have a second curvature, and so on, where the curvatures are different curvatures.

A layer stack 250 may be included under the semiconductor substrate 246. The layer stack 250 may include layers 252-258, which may include adhesion layers, passivation layers, glue layers, dielectric layers, and/or other types of layers. A plurality of ARC layers 260 may be included under the layer stack 250 in an oxide fill region 262 of the second semiconductor die 204. The ARC layers 260, including ARC layers 260a-260d, may be located above and/or over the grating couplers 220a-220d. For example, the ARC layer 260a may be located above and/or over the grating coupler 220a, the ARC layer 260b may be located above and/or over the grating coupler 220b, and so on. The quantity of ARC layers 260a-260d illustrated in FIG. 2A is an example, and other quantities of ARC layers 260 are within the scope of the present disclosure.

Each ARC layer 260 may include one or more layers and/or materials that are configured to reduce reflections of an optical signal. The materials and/or the properties of the one or more layers may be selected to achieve transmission of a particular wavelength or wavelength range of the optical signal, and to achieve reflection of other wavelengths or other wavelength ranges of the optical signal. In this way, the materials and/or the properties of the one or more layers of the ARC layers 260a-260d may be selected to split the optical signal into different wavelengths or different wavelength ranges that are then passed to respective grating couplers 220a-220d. For example, the materials and/or the properties of the one or more layers of the ARC layer 260a may be selected to achieve transmission of a first wavelength or a first wavelength range of the optical signal to the grating coupler 220a (and to block other wavelengths or other wavelength ranges from being transmitted to the grating coupler 220a), the materials and/or the properties of the one or more layers of the ARC layer 260b may be selected to achieve transmission of a second wavelength or a second wavelength range of the optical signal to the grating coupler 220b (and to block other wavelengths or other wavelength ranges from being transmitted to the grating coupler 220b), and so on. This enables each of the grating couplers 220a-220d to handle a respective wavelength or a respective wavelength range, which enables the bandwidth of the optical signal to be distributed across the grating couplers 220a-220d, as opposed to being handled by a single grating coupler. This enables the semiconductor photonics device 200 to process higher bandwidth signals than a semiconductor photonics device that includes only a single grating coupler.

As further shown in FIG. 2A, the second semiconductor die 204 may include a dielectric layer 264 adjacent to the oxide fill region 262. The dielectric layer 264 may include metallization layers 266 that are electrically coupled and/or physically coupled with bonding pads 268 in a dielectric layer 270 under the dielectric layer 264 and the oxide fill region 262. The metallization layers 266 and the bonding pads 244 may each include one or more conductive materials, such as copper (Cu), gold (Au), silver (Ag), nickel (Ni), tin (Sn), ruthenium (Ru), cobalt (Co), tungsten (W), titanium (Ti), one or more metals, one or more conductive ceramics, and/or another type of conductive materials. The dielectric layer 264 and the dielectric layer 270 may each include a dielectric material (e.g., the same dielectric material and/or different dielectric materials), such as a silicon oxide (SiOₓ), a silicon nitride (SiₓN_{y}), a silicon oxynitride (SiON), tetraethyl orthosilicate oxide, phosphosilicate glass (PSG), borophosphosilicate glass (BPSG), fluorinated silicate glass (FSG), carbon doped silicon oxide, and/or another dielectric material. A passivation layer 272 may be included over the top surface of the semiconductor substrate 246 and over the micro lenses 248.

The first semiconductor die 202 and the second semiconductor die 204 may be bonded at the bonding interface 206 such that the bonding pads 244 and the bonding pads 268 are coupled, and such that the dielectric layer 238 and the dielectric layer 270 are coupled. Thus, the bond between the first semiconductor die 202 and the second semiconductor die 204 may be a hybrid bond, in that the bonding pads 244 and the bonding pads 268 are bonded by a metal-to-metal bond, and the dielectric layer 238 and the dielectric layer 270 are bonded by a dielectric-to-dielectric bond.

FIG. 2B illustrates a top-down view of a portion of the semiconductor photonics device 200. As shown in FIG. 2B, the semiconductor photonics device 200 may include a plurality of sets of grating couplers 220, micro lenses 248, and ARC layers 260, where each set may be configured to handle a particular wavelength or wavelength range. For example, a first set may include a first grating coupler 220, a first micro lens 248, and a first ARC layer 260. The first set may be configured to direct a first wavelength or a first wavelength range of an optical signal to and/or from the waveguide 218. A second set may include a second grating coupler 220, a second micro lens 248, and a second ARC layer 260. The second set may be configured to direct a second wavelength or a second wavelength range of the optical signal to and/or from the waveguide 218. Other sets of grating couplers 220, micro lenses 248, and ARC layers 260 may be configured in a similar manner. For each set, the grating coupler 220, the micro lens 248, and the ARC layer 260 may be vertically arranged and vertically aligned such that the grating coupler 220, the micro lens 248, and the ARC layer 260 vertically overlap.

FIG. 2C illustrates an example of splitting wavelengths or wavelength ranges of an optical signal 274 using the sets of grating couplers 220, micro lenses 248, and ARC layers 260. As shown in FIG. 2C, a first wavelength (or a first wavelength range) 274a may be directed by the micro lens 248a to the grating coupler 220a through the ARC layer 260a, where the ARC layer 260a is configured to reduce and/or minimize reflections of the first wavelength 274a and to reflect other wavelengths (or other wavelength ranges) of the optical signal 274. The first wavelength 274a may carry a first multiplexed data signal of the optical signal 274.

A second wavelength (or a second wavelength range) 274b may be directed by the micro lens 248b to the grating coupler 220b through the ARC layer 260b, where the ARC layer 260b is configured to reduce and/or minimize reflections of the first wavelength 274b and to reflect other wavelengths (or other wavelength ranges) of the optical signal 274. The second wavelength 274b may carry a second multiplexed data signal of the optical signal 274.

A third wavelength (or a third wavelength range) 274c may be directed by the micro lens 248c to the grating coupler 220c through the ARC layer 260c, where the ARC layer 260c is configured to reduce and/or minimize reflections of the third wavelength 274c and to reflect other wavelengths (or other wavelength ranges) of the optical signal 274. The third wavelength 274c may carry a third multiplexed data signal of the optical signal 274.

A fourth wavelength (or a fourth wavelength range) 274d may be directed by the micro lens 248d to the grating coupler 220d through the ARC layer 260d, where the ARC layer 260d is configured to reduce and/or minimize reflections of the fourth wavelength 274d and to reflect other wavelengths (or other wavelength ranges) of the optical signal 274. The fourth wavelength 274d may carry a fourth multiplexed data signal of the optical signal 274.

The quantity of wavelength components of the optical signal 274 illustrated in FIG. 2C is an example, and other quantities are within the scope of the present disclosure.

FIG. 2D illustrates an example of an ARC layer 260. As shown in FIG. 2D, an ARC layer 260 may include a multiple-layer structure in which a plurality of first layers 276 are vertically arranged with a plurality of second layers 278 in an alternating manner. In other words, the first layers 276 alternate with the second layers 278 in a direction that is approximately perpendicular to a direction in which the ARC layer 260 extends. In some implementations, one or more properties of the plurality of first layers 276 and one or more properties of the plurality of second layers 278 may be selected to permit transmission of a particular wavelength or a particular wavelength range of the optical signal 274 through the ARC layer 260. For example, the refractive indices of the first layers 276 and the second layers 278 may be different and may be selected to permit transmission of a particular wavelength or a particular wavelength range of the optical signal 274 through the ARC layer 260. In other words, each of the first layers 276 may have a first refractive index, each of the second layers 278 may have a second refractive index, and the first refractive index and the second refractive index may be different refractive indices and may be selected to permit transmission of a particular wavelength or a particular wavelength range of the optical signal 274 through the ARC layer 260.

As another example, the thicknesses of the first layers 276 and the second layers 278 may be different and may be selected to permit transmission of a particular wavelength or a particular wavelength range of the optical signal 274 through the ARC layer 260. In other words, each of the first layers 276 may have a first thickness (e.g., individual thicknesses for each first layer 276), each of the second layers 278 may have a second thickness (e.g., individual thicknesses for each second layer 278), and the first thickness and the second thickness may be different thicknesses and may be selected to permit transmission of a particular wavelength or a particular wavelength range of the optical signal 274 through the ARC layer 260. As an example, the first layers 276 may each have a thickness corresponding to approximately half of the wavelength (e.g., λ/2) that is to be transmitted through the ARC layer 260, and the second layers may each have a thickness corresponding to approximately one quarter of the wavelength (e.g., λ/4) that is to be transmitted through the ARC layer 260.

FIGS. 2E and 2F illustrate examples of operation of the semiconductor photonics device 200. FIG. 2E illustrates an example reception operation in which the semiconductor photonics device 200 receives the optical signal 274. FIG. 2F illustrates an example transmission operation in which the semiconductor photonics device 200 transmits the optical signal 274.

As shown in FIG. 2E, the optical signal 274 may be received through the micro lenses 248 (e.g., from an optical fiber cable). The micro lenses 248 may each be configured to direct a particular wavelength or particular wavelength range to an associated ARC layer 260, which passes the particular wavelength or the particular wavelength range to an associated grating coupler 220, as described in connection with FIG. 2C. The grating couplers 220 provide the wavelengths or wavelength ranges of the optical signal 274 to the waveguide 218, which directs the wavelengths or wavelength ranges of the optical signal 274 to the optical transceiver 216. The optical transceiver 216 converts the wavelengths or wavelength ranges of the optical signal 274 to electrical output signals 280, and provides the electrical output signals 280 to the conductive pads 228 through the metallization layers 214, through the connection structures 240, through the bonding pads 244 and 268, through the metallization layers 266, through the connection structures 230, and through the metallization layers 226. Each of the wavelengths or wavelength ranges of the optical signal 274 may be converted to a separate electrical output signal 280 that carries the data stream of the associated wavelength or associated wavelength range of the optical signal 274. In this way, the grating couplers 220, the micro lenses 248, and the ARC layers 260 enable the optical signal 274 to be demultiplexed and converted to multiple electrical output signals 280.

As shown in FIG. 2F, electrical input signals 282 carrying separate data streams may be provided to the optical transceiver 216 from the conductive pads 228 through the metallization layers 214, through the connection structures 240, through the bonding pads 244 and 268, through the metallization layers 266, and through the connection structures 230, and through the metallization layers 226. The optical transceiver 216 converts the electrical input signals 282 into different wavelengths or wavelength ranges of the optical signal 274. The wavelengths or wavelength ranges of the optical signal 274 may be provided to respective grating couplers 220 through the waveguide 218. The grating couplers 220 direct the respective wavelengths or respective wavelength ranges through associated ARC layers 260 and associated micro lenses 248, which multiplex the wavelengths or wavelength ranges of the optical signal 274. The optical signal 274 may be transmitted through the micro lenses 248 (e.g., to an optical fiber cable).

As indicated above, FIGS. 2A-2F are provided as an example. Other examples may differ from what is described with regard to FIGS. 2A-2F.

FIGS. 3A-3H are diagrams of an example implementation 300 of forming the first semiconductor die 202 described herein. In some implementations, one or more of the semiconductor processing operations described in connection with the example implementation 300 may be performed using one or more of the semiconductor processing tools 102-114 and/or by the wafer/die transport tool 116. In some implementations, one or more of the semiconductor processing operations described in connection with the example implementation 300 may be performed using another semiconductor processing tool.

Turning to FIG. 3A, a substrate may be provided. The substrate may include a silicon on insulator (SOI) substrate that includes a semiconductor substrate 208 (e.g., a silicon (Si) substrate and/or another type of semiconductor substrate), a portion of the dielectric layer 212 (e.g., a buried oxide or bottom oxide (BOX) layer and/or another type of insulator layer) over and/or on the semiconductor substrate 208, and a semiconductor layer 302 (e.g., a silicon (Si) layer and/or another type of semiconductor layer) over and/or on the portion of the dielectric layer 212. Alternatively, the semiconductor substrate 208 may be provided as a semiconductor wafer, and a deposition tool 102 may be used to form the portion of the dielectric layer 212 over and/or on the semiconductor substrate 208, and another deposition tool 102 may be used to form the semiconductor layer 302 over and/or on the dielectric layer 212. A deposition tool 102 may be used to form the dielectric layer 212 using a CVD technique, a PVD technique, an oxidation technique (e.g., a thermal oxidation technique), and/or another type of deposition technique. A deposition tool 102 may be used to form the semiconductor layer 302 using a CVD technique, a PVD technique, an epitaxy technique, and/or another type of deposition technique.

As shown in FIG. 3B, the optical transceiver 216, the waveguide 218, and the grating couplers 220 may be formed from the semiconductor layer 302 in the device region 210 of the first semiconductor die 202. Additional portions of the dielectric layer 212 may be formed around the optical transceiver 216, the waveguide 218, and the grating couplers 220. In some implementations, a pattern in a photoresist layer is used to etch the semiconductor layer 302 to form the optical transceiver 216, the waveguide 218, and the grating couplers 220. In these implementations, a deposition tool 102 may be used to form the photoresist layer on the semiconductor layer 302. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the semiconductor layer 302 based on the pattern to form the optical transceiver 216, the waveguide 218, and the grating couplers 220 in the semiconductor layer 302. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor layer 302 based on a pattern. A deposition tool 102 may be used to deposit the additional portions of the dielectric layer 212 using a CVD technique, a PVD technique, an oxidation technique (e.g., a thermal oxidation technique), and/or another type of deposition technique.

In some implementations, an ion implantation tool 114 may be used to dope various portions of the optical transceiver 216 to form a P-N junction or a P-I-N junction, where an intrinsic/undoped region is included between a p-type doped region and n-typed doped region. The ion implantation tool 114 may be used to implant dopants into the semiconductor layer 302 to dope the various portions of the optical transceiver 216.

As shown in FIG. 3C, the metallization layers 214 may be formed in additional portions of the dielectric layer 212 to build up the device region 210. In some implementations, the metallization layers 214 may be referred to as the back end of line (BEOL) region of the first semiconductor die 202. In some implementations, the metallization layers 214 may be built up in sequential layers. For example, a deposition tool 102 may deposit a portion of the dielectric layer 212, an exposure tool 104, a developer tool 106, and an etch tool 108 may be used to form recesses in the portion of the dielectric layer 212, and a deposition tool 102 and/or a plating tool 112 may be used to form a first metallization layer 214 (e.g., an M1 metallization layer) in the recesses. Similar operations may be performed to form additional metallization layers 214 (e.g., an M2 metallization layer, an M3 metallization layer, and so on).

As shown in FIG. 3D, the dielectric layer 234 may be formed over and/or on the dielectric layer 212. A deposition tool 102 may be used to deposit the dielectric layer 234 using a CVD technique, a PVD technique, an oxidation technique (e.g., a thermal oxidation technique), and/or another type of deposition technique. In some implementations, a planarization tool 110 is used to planarize the dielectric layer 234 after the dielectric layer 234 is deposited.

As shown in FIG. 3E, contacts 242 may be formed in and/or on the dielectric layer 234 such that the contacts 242 are electrically coupled and/or physically coupled with one or more metallization layers 214. An exposure tool 104, a developer tool 106, and an etch tool 108 may be used to form recesses in the dielectric layer 234 to expose the one or more metallization layers 214, and a deposition tool 102 and/or a plating tool 112 may be used to form the contacts 242 in the recesses.

As shown in FIG. 3F, the dielectric layer 236 may be formed over and/or on the dielectric layer 234. The dielectric layer 236 may cover the contacts 242. A deposition tool 102 may be used to deposit the dielectric layer 236 using a CVD technique, a PVD technique, an oxidation technique (e.g., a thermal oxidation technique), and/or another type of deposition technique. In some implementations, a planarization tool 110 is used to planarize the dielectric layer 236 after the dielectric layer 236 is deposited.

As shown in FIG. 3G, connection structures 240 are formed through the dielectric layers 234 and 236 such that the connection structures 240 are electrically coupled and/or physically coupled with one or more of the metallization layers 214. An exposure tool 104, a developer tool 106, and an etch tool 108 may be used to form recesses through the dielectric layers 234 and 236 to expose the one or more metallization layers 214, and a deposition tool 102 and/or a plating tool 112 may be used to form the connection structures 240 in the recesses.

As shown in FIG. 3H, the dielectric layer 238 may be formed over and/or on the dielectric layer 236. The dielectric layer 238 may cover the connection structures 240. A deposition tool 102 may be used to deposit the dielectric layer 238 using a CVD technique, a PVD technique, an oxidation technique (e.g., a thermal oxidation technique), and/or another type of deposition technique. In some implementations, a planarization tool 110 is used to planarize the dielectric layer 238 after the dielectric layer 238 is deposited.

As further shown in FIG. 3H, bonding pads 244 are formed through the dielectric layer 238 such that the bonding pads 244 are electrically coupled and/or physically coupled with one or more of the connection structures 240. An exposure tool 104, a developer tool 106, and an etch tool 108 may be used to form recesses through the dielectric layer 238 to expose the one or more connection structures 240, and a deposition tool 102 and/or a plating tool 112 may be used to form the bonding pads 244 in the recesses.

As indicated above, FIGS. 3A-3H are provided as an example. Other examples may differ from what is described with regard to FIGS. 3A-3H.

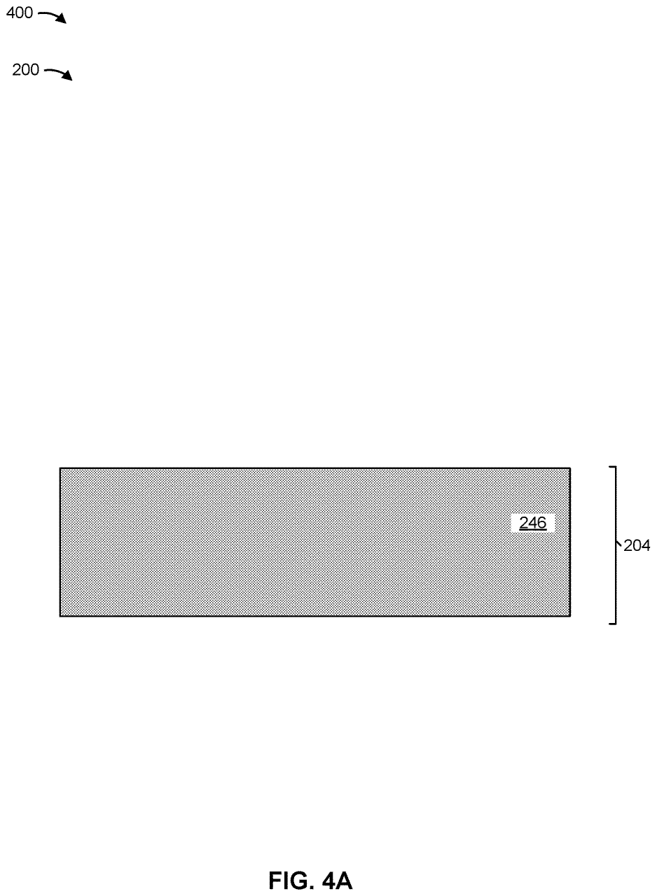

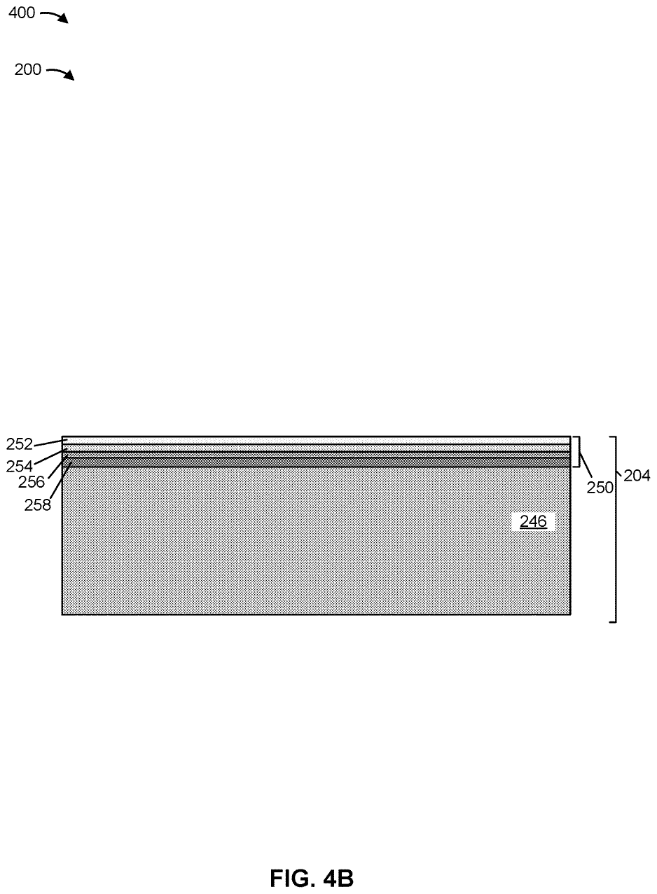

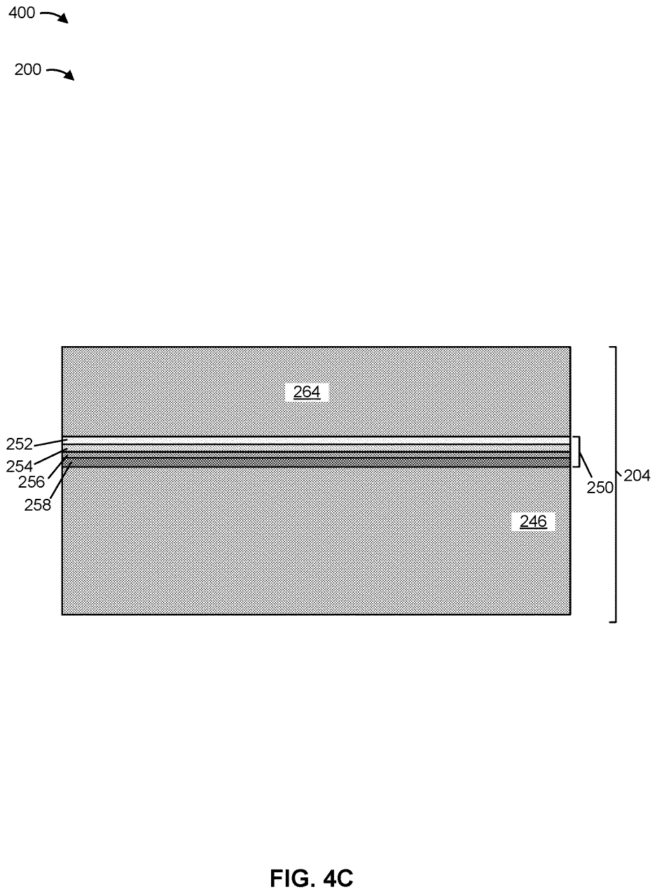

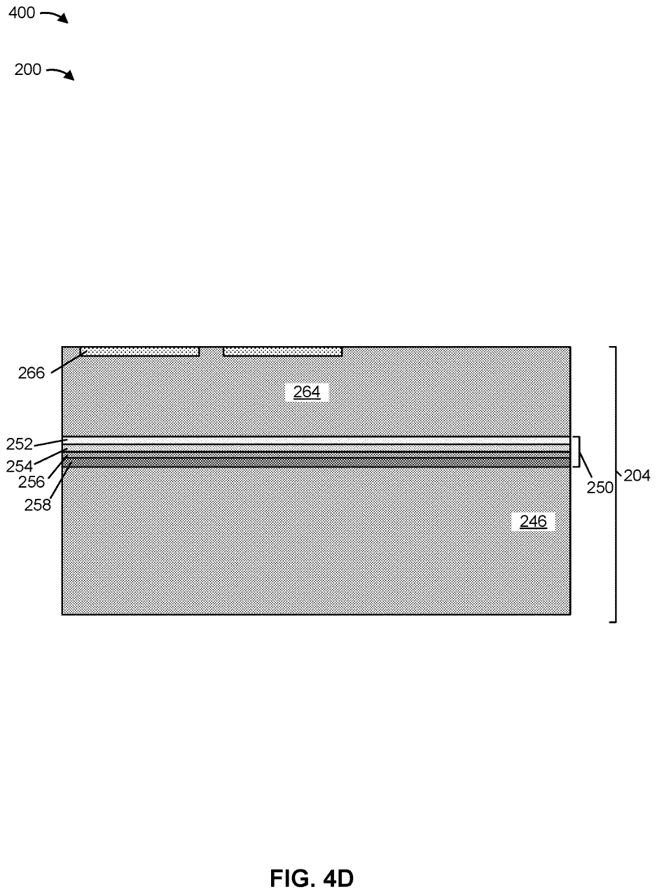

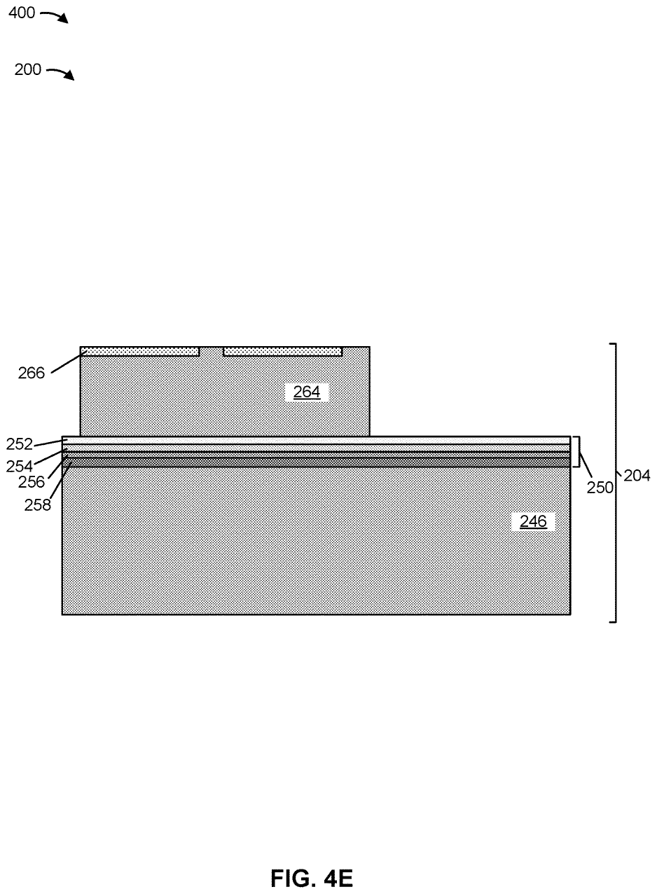

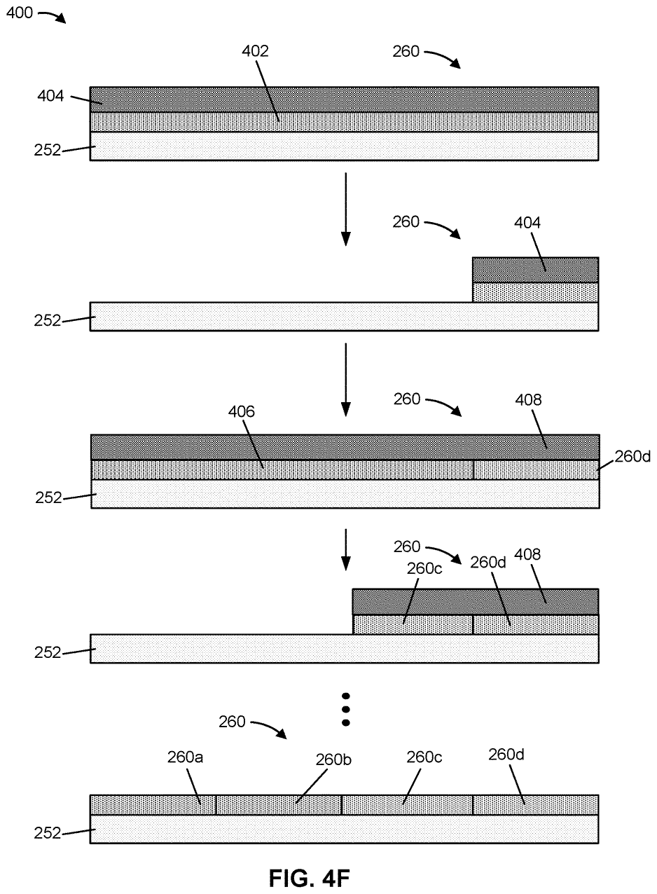

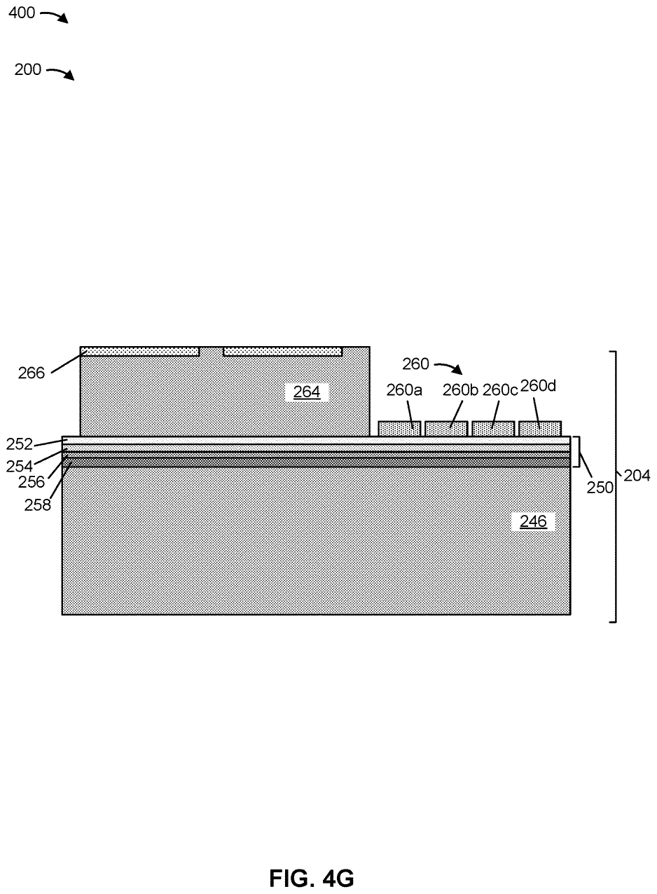

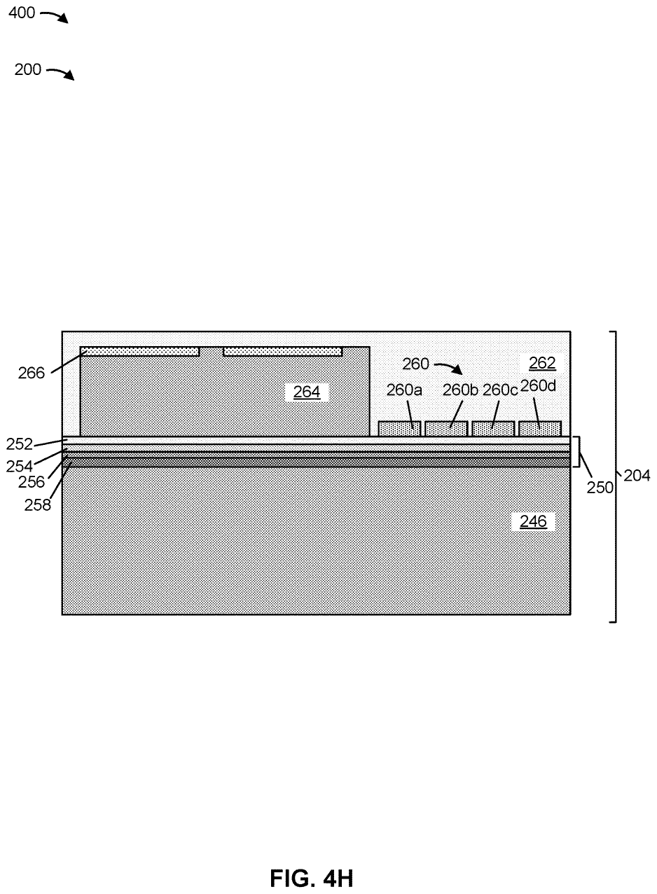

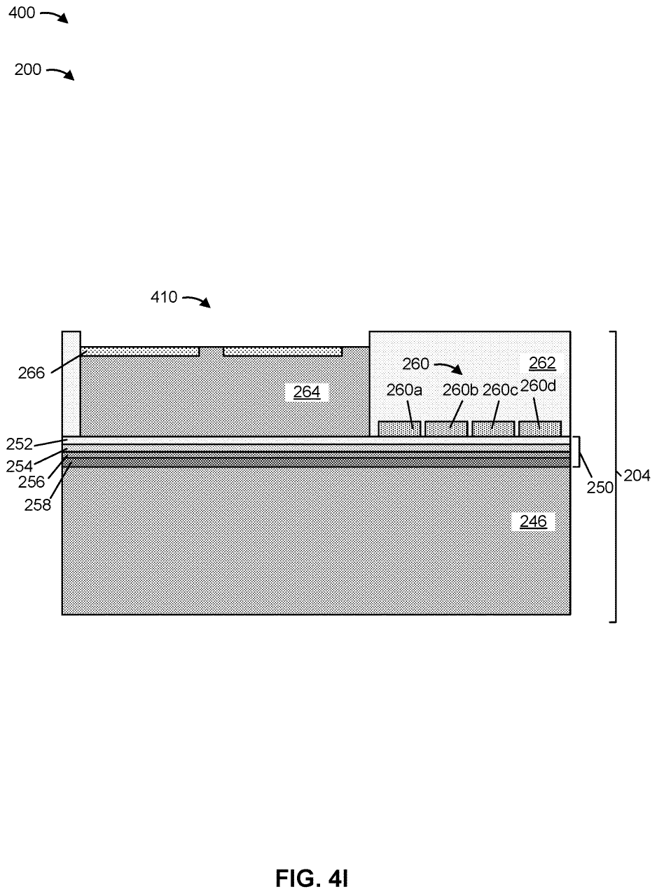

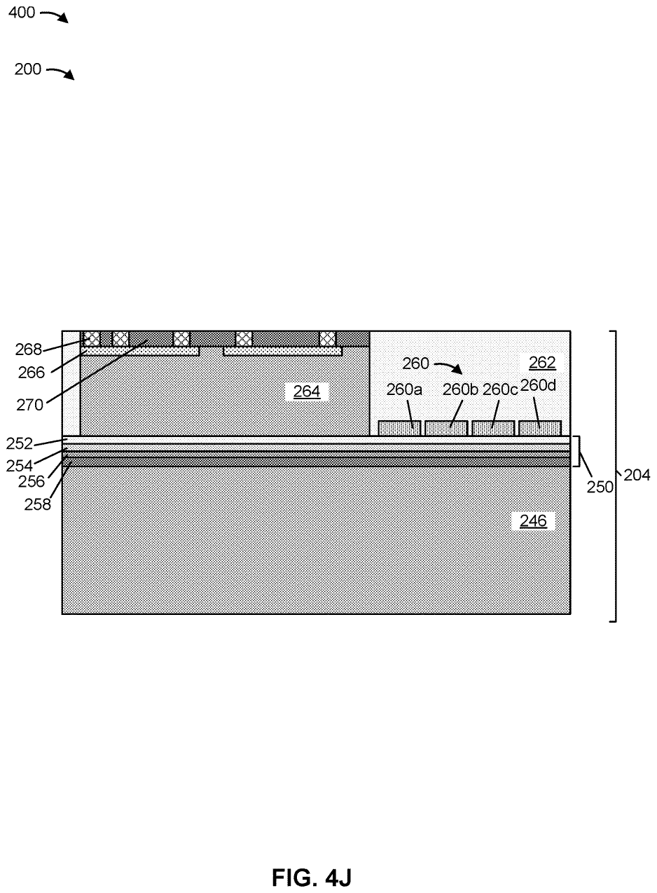

FIGS. 4A-4J are diagrams of an example implementation 400 of forming the second semiconductor die 204 described herein. In some implementations, one or more of the semiconductor processing operations described in connection with the example implementation 400 may be performed using one or more of the semiconductor processing tools 102-114 and/or by the wafer/die transport tool 116. In some implementations, one or more of the semiconductor processing operations described in connection with the example implementation 400 may be performed using another semiconductor processing tool.

Turning to FIG. 4A, a substrate may be provided. The substrate may include the semiconductor substrate 246, which may include a silicon (Si) substrate and/or another type of semiconductor substrate. The semiconductor substrate 246 may be provided as a semiconductor wafer (e.g., a silicon wafer) and/or another type of semiconductor workpiece.

As shown in FIG. 4B, a deposition tool 102 may be used to form the layer stack 250 using a CVD technique, a PVD technique, an oxidation technique (e.g., a thermal oxidation technique), and/or another type of deposition technique. For example, a deposition tool 102 may be used to deposit the layer 258 over and/or on the semiconductor substrate 246, a deposition tool 102 may be used to deposit the layer 256 over and/or on the layer 258, a deposition tool 102 may be used to deposit the layer 254 over and/or on the layer 256, and/or a deposition tool 102 may be used to deposit the layer 252 over and/or on the layer 254. In some implementations, a planarization tool 110 may be used to planarize one or more of the layers 252-258 in the layer stack 250.

As shown in FIG. 4C, the dielectric layer 264 may be formed over and/or on the layer stack 250. A deposition tool 102 may be used to deposit the dielectric layer 264 using a CVD technique, a PVD technique, an oxidation technique (e.g., a thermal oxidation technique), and/or another type of deposition technique. In some implementations, a planarization tool 110 is used to planarize the dielectric layer 264 after the dielectric layer 264 is deposited.

As shown in FIG. 4D, metallization layers 266 may be formed in the dielectric layer 264. In some implementations, a pattern in a photoresist layer is used to etch the dielectric layer 264 to form recesses in the dielectric layer 264. In these implementations, a deposition tool 102 may be used to form the photoresist layer on the dielectric layer 264. An exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 264 based on the pattern to form the recesses in the dielectric layer 264. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 264 based on a pattern.

The deposition tool 102 and/or the plating tool 112 may be used to deposit the metallization layers 266 in a CVD operation, a PVD operation, an ALD operation, an electroplating operation, another deposition operation described above in connection with FIG. 1, and/or another suitable deposition operation. In some implementations, a seed layer is first deposited, and the metallization layers 266 are deposited on the seed layer. In some implementations, the planarization tool 110 may be used to planarize the metallization layers 266 after the metallization layers 266 are deposited.

As shown in FIG. 4E, the dielectric layer 264 may be etched to remove portions of the dielectric layer 264. In some implementations, a pattern in a photoresist layer is used to etch the dielectric layer 264 to remove the portions of the dielectric layer 264. In these implementations, a deposition tool 102 may be used to form the photoresist layer on the dielectric layer 264 and/or on the metallization layers 266. An exposure tool 104 may be used to expose the photoresist layer to a radiation source to pattern the photoresist layer. The developer tool 106 may be used to develop and remove portions of the photoresist layer to expose the pattern. The etch tool 108 may be used to etch the dielectric layer 264 based on the pattern to remove the portions of the dielectric layer 264. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 264 based on a pattern.

As shown in FIGS. 4F and 4G, the ARC layers 260 may be formed over and/or on a portion of the layer 252 that is exposed after removing the portions of the dielectric layer 264. As shown in FIG. 4F, forming the ARC layers 260 may include forming a layer 402 of ARC material on the layer 252 (e.g., using a deposition tool 102), forming a photoresist layer 404 on the layer 402 of ARC material (e.g., using a deposition tool 102), forming a pattern in the photoresist layer 404 (e.g., using an exposure tool 104 and a developer tool 106), and removing a portion of the layer 402 of ARC material based on the pattern (e.g., using an etch tool 108) to form an ARC layer 260d. Forming the ARC layers 260 may include forming a layer 406 of ARC material on the layer 252 and adjacent to the ARC layer 260d (e.g., using a deposition tool 102), forming a photoresist layer 408 on the layer 406 of ARC material and on the ARC layer 260d (e.g., using a deposition tool 102), forming a pattern in the photoresist layer 408 (e.g., using an exposure tool 104 and a developer tool 106), and removing a portion of the layer 406 of ARC material based on the pattern (e.g., using an etch tool 108) to form an ARC layer 260c. Similar operations may be performed to form the ARC layers 260b and 260a.

As shown in FIG. 4H, the oxide fill region 262 may be formed over and/or on the ARC layer 260, over and/or on the dielectric layer 264, and over and/or on the metallization layers 266. A deposition tool 102 may be used to deposit the oxide fill region 262 using a CVD technique, a PVD technique, an oxidation technique (e.g., a thermal oxidation technique), and/or another type of deposition technique. In some implementations, a planarization tool 110 is used to planarize the oxide fill region 262 after the oxide fill region 262 is deposited.

As shown in FIG. 4I, a recess 410 may be formed through the oxide fill region 262 to expose the dielectric layer 264 and the metallization layers 266. In some implementations, a pattern in a photoresist layer is used to etch the oxide fill region 262 to form the recess 410. In these implementations, the deposition tool 102 may be used to form the photoresist layer on the oxide fill region 262. The exposure tool 104 may be used to expose the photoresist layer to a radiation source to pattern the photoresist layer. The developer tool 106 may be used to develop and remove portions of the photoresist layer to expose the pattern. The etch tool 108 may be used to etch the oxide fill region 262 based on the pattern to form the recess 410 in the oxide fill region 262. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the oxide fill region 262 based on a pattern.

As shown in FIG. 4J, the dielectric layer 270 may be formed in the recess 410 over and/or on the dielectric layer 264. The dielectric layer 270 may cover the metallization layers 266. A deposition tool 102 may be used to deposit the dielectric layer 270 using a CVD technique, a PVD technique, an oxidation technique (e.g., a thermal oxidation technique), and/or another type of deposition technique. In some implementations, a planarization tool 110 is used to planarize the dielectric layer 270 after the dielectric layer 270 is deposited such that a top surface of the dielectric layer 270 and a top surface of the oxide fill region 262 are co-planar.

As further shown in FIG. 4J, bonding pads 268 are formed through the dielectric layer 270 such that the bonding pads 268 are electrically coupled and/or physically coupled with one or more of the metallization layers 266. An exposure tool 104, a developer tool 106, and an etch tool 108 may be used to form recesses through the dielectric layer 270 to expose the one or more metallization layers 266, and a deposition tool 102 and/or a plating tool 112 may be used to form the bonding pads 268 in the recesses.

As indicated above, FIGS. 4A-4J are provided as an example. Other examples may differ from what is described with regard to FIGS. 4A-4J.

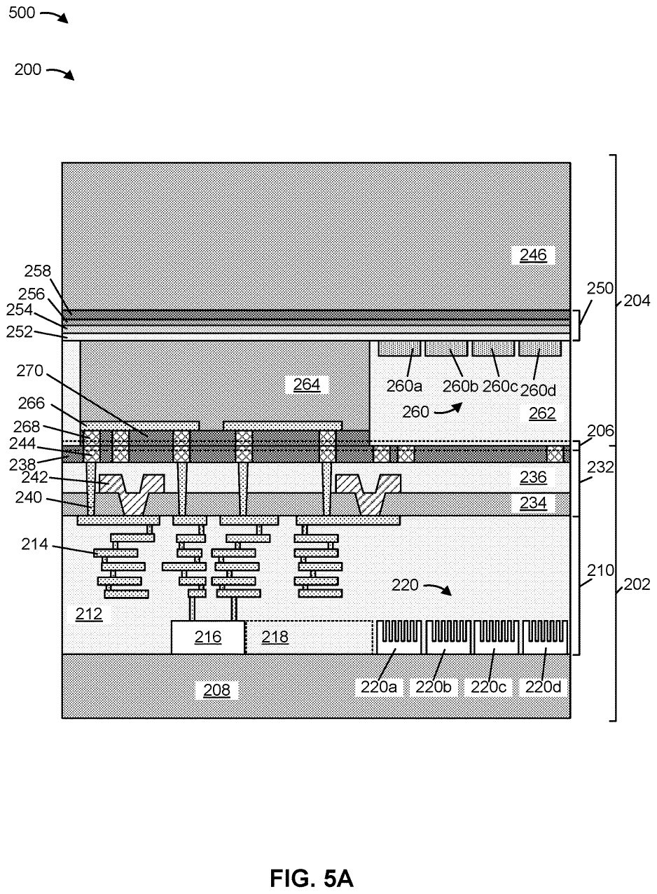

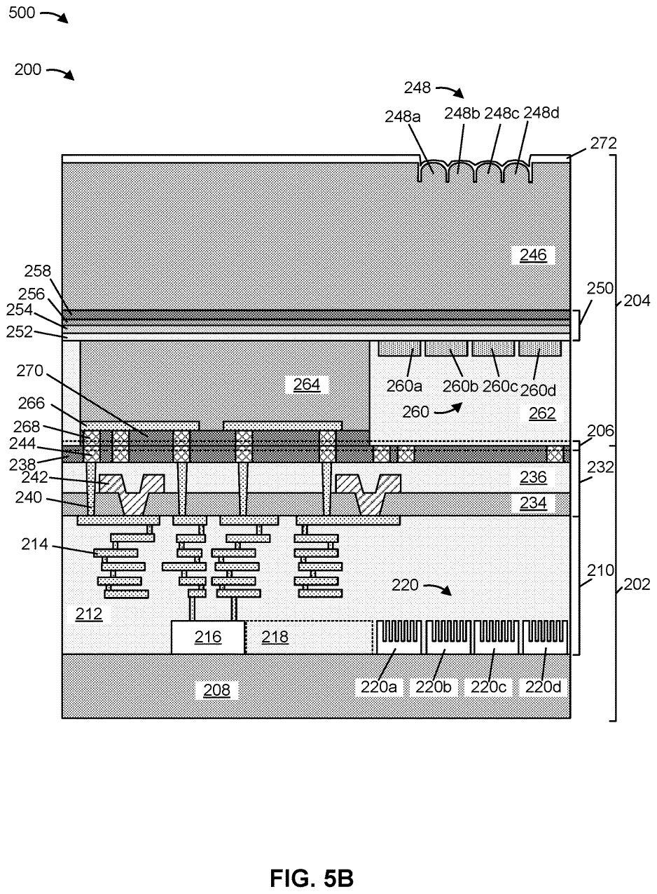

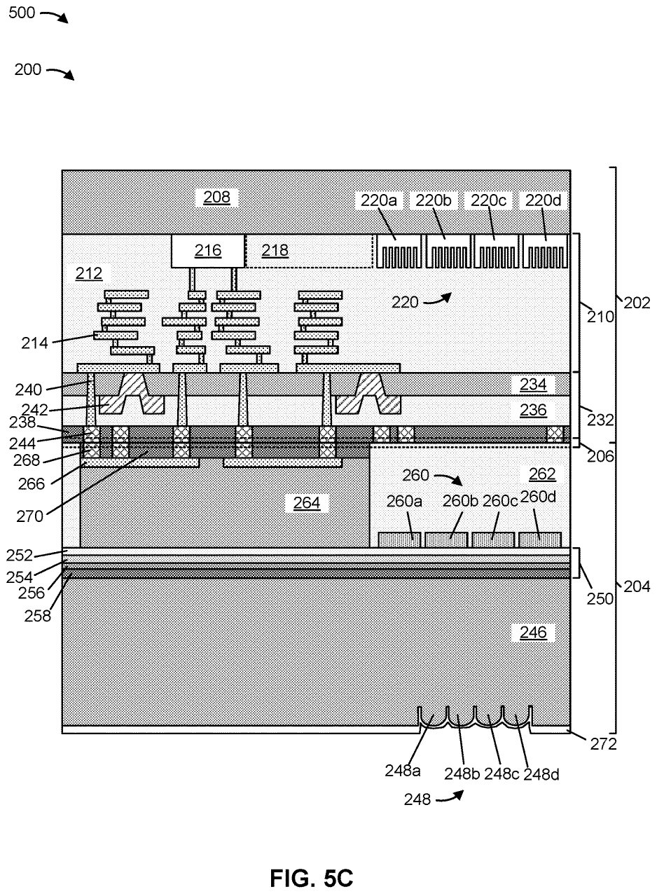

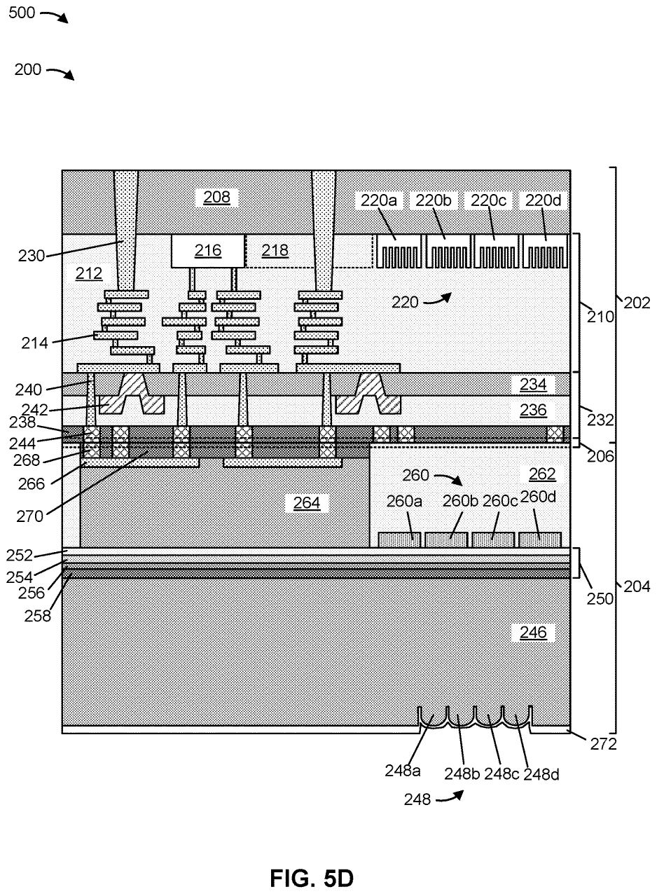

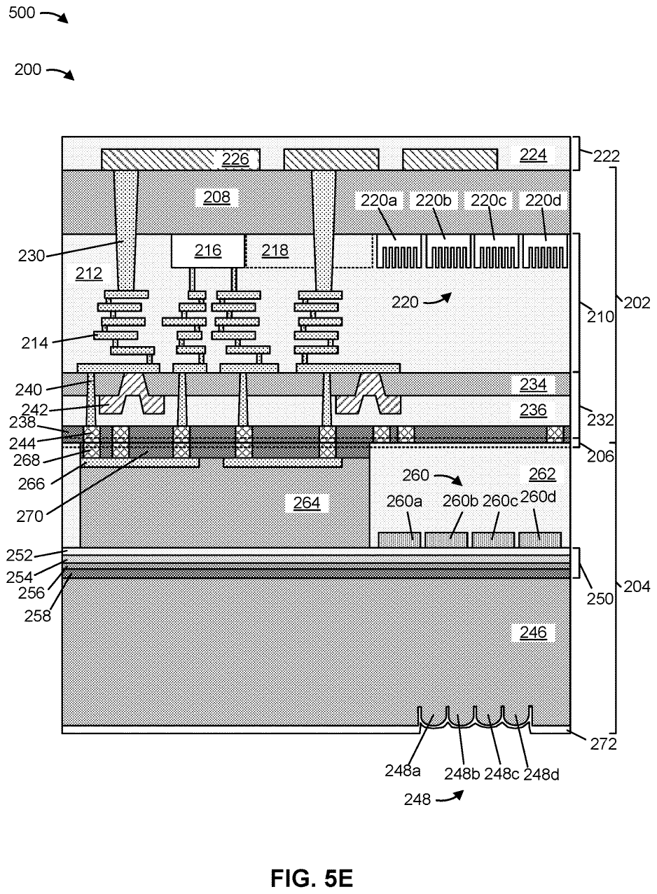

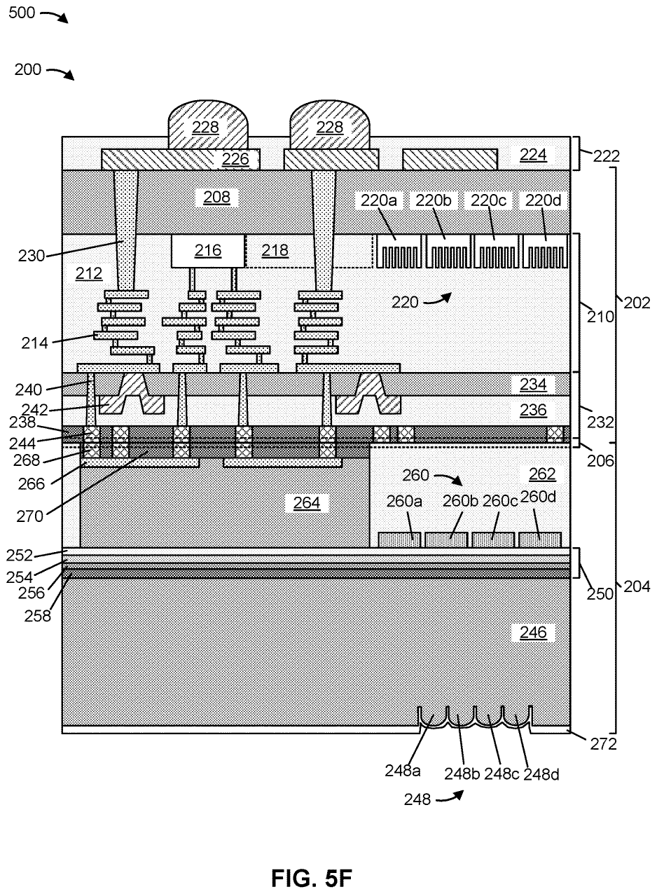

FIGS. 5A-5F are diagrams of an example implementation 500 of forming the semiconductor photonics device 200 described herein. In some implementations, one or more of the semiconductor processing operations described in connection with the example implementation 500 may be performed using one or more of the semiconductor processing tools 102-114 and/or by the wafer/die transport tool 116. In some implementations, one or more of the semiconductor processing operations described in connection with the example implementation 500 may be performed using another semiconductor processing tool.

As shown in FIG. 5A, the first semiconductor die 202 and the second semiconductor die 204 may be bonded at the bonding interface 206. The bonding interface 206 may include a metal-to-metal bond between the bonding pads 244 of the first semiconductor die 202 and the bonding pads 268 of the second semiconductor die 204. The bonding interface 206 may further include a dielectric-to-dielectric bond between the dielectric layer 238 of the first semiconductor die 202 and the dielectric layer 264 of the second semiconductor die 204.

As shown in FIG. 5B, backside processing may be performed on the second semiconductor die 204 after the first semiconductor die 202 and the second semiconductor die 204 are bonded. The backside processing may include forming the micro lenses 248 in a backside surface of the semiconductor substrate 246, and forming the passivation layer 272 on the backside surface of the semiconductor substrate 246 after forming the micro lenses 248. A micro lens 248a may be formed over the ARC layer 260a and over the grating coupler 220a, a micro lens 248b may be formed over the ARC layer 260b and over the grating coupler 220b, and so on.

In some implementations, a pattern in a photoresist layer is used to etch the semiconductor substrate 246 to form the micro lenses 248. In these implementations, a deposition tool 102 may be used to form the photoresist layer on the semiconductor substrate 246. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the semiconductor substrate 246 based on the pattern to form the micro lenses 248 in the semiconductor substrate 246. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor substrate 246 based on a pattern.

A deposition tool 102 may be used to deposit the passivation layer 272 in a PVD operation, an ALD operation, a CVD operation, an epitaxy operation, an oxidation operation, another type of deposition operation described in connection with FIG. 1, and/or another suitable deposition operation. In some implementations, the passivation layer 272 may conform to the contours of the micro lenses 248.

As shown in FIGS. 5C-5F, backside processing may be performed on the first semiconductor die 202 after the first semiconductor die 202 and the second semiconductor die 204 are bonded. As shown in FIG. 5D, the backside processing may include forming the connection structures 230 from a backside surface of the first semiconductor die 202 through the semiconductor substrate 208 and into the dielectric layer 212 to one or more metallization layers 214.

In some implementations, a pattern in a photoresist layer is used to etch the semiconductor substrate 208 and the dielectric layer 212 to form recesses through the semiconductor substrate 208 and into the dielectric layer 212. Portions of one or more metallization layers 214 may be exposed through the recesses. In these implementations, a deposition tool 102 may be used to form the photoresist layer on the backside surface of the semiconductor substrate 208. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the semiconductor substrate 208 and the dielectric layer 212 based on the pattern to form the recesses. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the semiconductor substrate 208 and/or the dielectric layer 212 based on a pattern.

A deposition tool 102 and/or a plating tool 112 may be used to deposit the connection structures 230 in a CVD operation, a PVD operation, an ALD operation, an electroplating operation, another deposition operation described above in connection with FIG. 1, and/or another suitable deposition operation. In some implementations, a seed layer is first deposited, and the connection structures 230 are deposited on the seed layer. In some implementations, the planarization tool 110 may be used to planarize the connection structures 230 after the connection structures 230 are deposited.

As shown in FIG. 5E, the metallization layers 226 may be formed over and/or on the backside surface of the semiconductor substrate 208 such that the metallization layers 226 are electrically coupled and/or physically coupled with one or more of the connection structures 230. A deposition tool 102 and/or a plating tool 112 may be used to deposit the metallization layers 226 in a CVD operation, a PVD operation, an ALD operation, an electroplating operation, another deposition operation described above in connection with FIG. 1, and/or another suitable deposition operation. In some implementations, a seed layer is first deposited, and the metallization layers 226 are deposited on the seed layer. In some implementations, the planarization tool 110 may be used to planarize the metallization layers 226 after the metallization layers 226 are deposited. In some implementations, a layer of conductive material is deposited on the backside surface of the semiconductor substrate 208, and an etch tool 108 is used to remove portions of the layer of conductive material, where remaining portions of the layer of conductive material correspond to the metallization layers 226.

As further shown in FIG. 5E, the electrically insulating layer 224 may be formed over and/or on the backside surface of the semiconductor substrate 208. The electrically insulating layer 224 may encapsulate the metallization layers 226. A deposition tool 102 may be used to deposit a first portion of the electrically insulating layer 224 using a CVD technique, a PVD technique, an oxidation technique (e.g., a thermal oxidation technique), and/or another type of deposition technique. In some implementations, a deposition tool 102 may deposit the first portion of the electrically insulating layer 224 in liquid form, which may be cured to remove solvents from the first portion of the electrically insulating layer 224 to cause the electrically insulating layer 224 to solidify and harden. In some implementations, a planarization tool 110 is used to planarize the first portion of the electrically insulating layer 224 after the first portion of the electrically insulating layer 224.

As shown in FIG. 5F, conductive pads 228 may be attached to the semiconductor photonics device 200. In particular, the conductive pads 228 may be attached to the metallization layers 226 on the backside of the second semiconductor die 204.

As indicated above, FIGS. 5A-5F are provided as an example. Other examples may differ from what is described with regard to FIGS. 5A-5F.

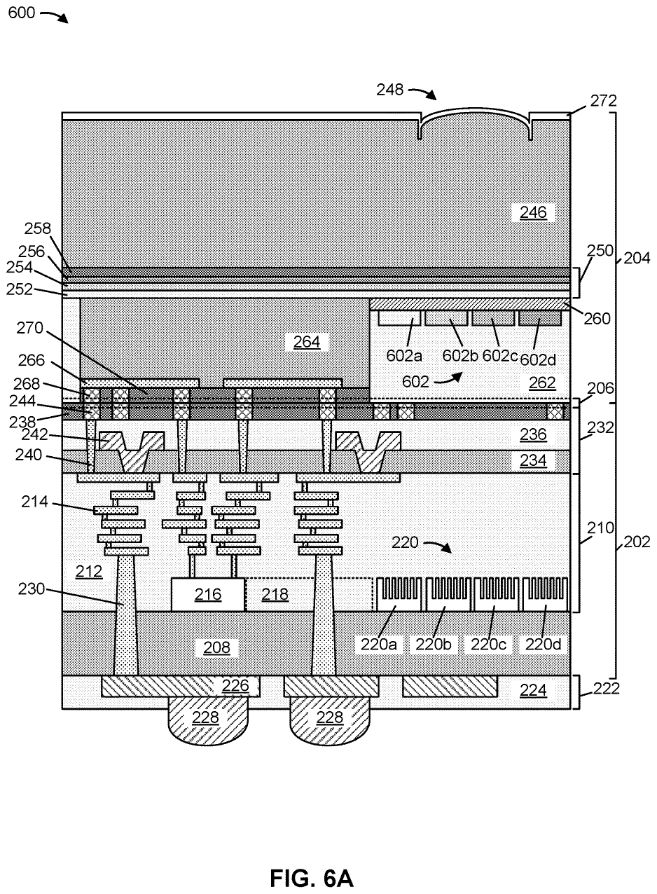

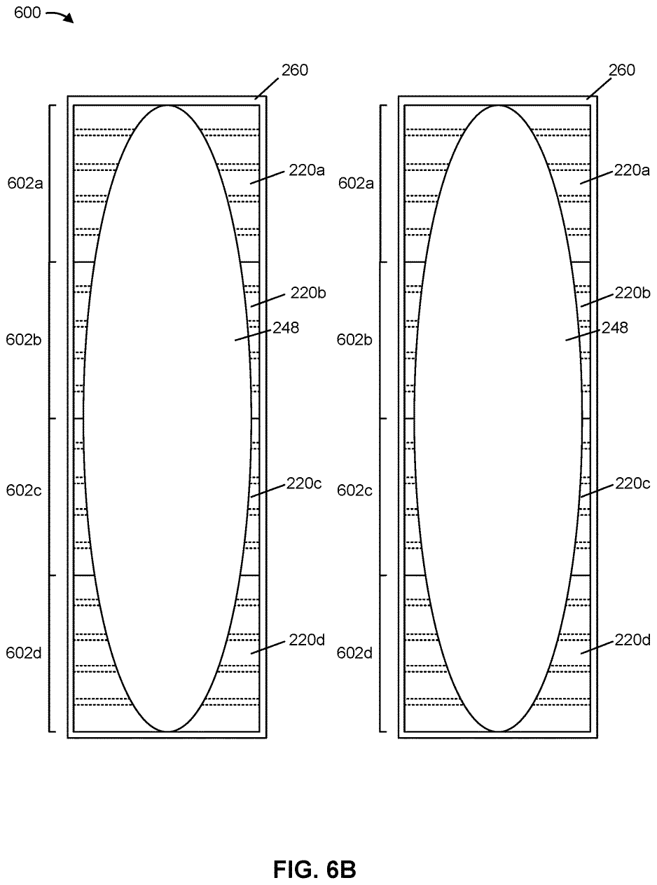

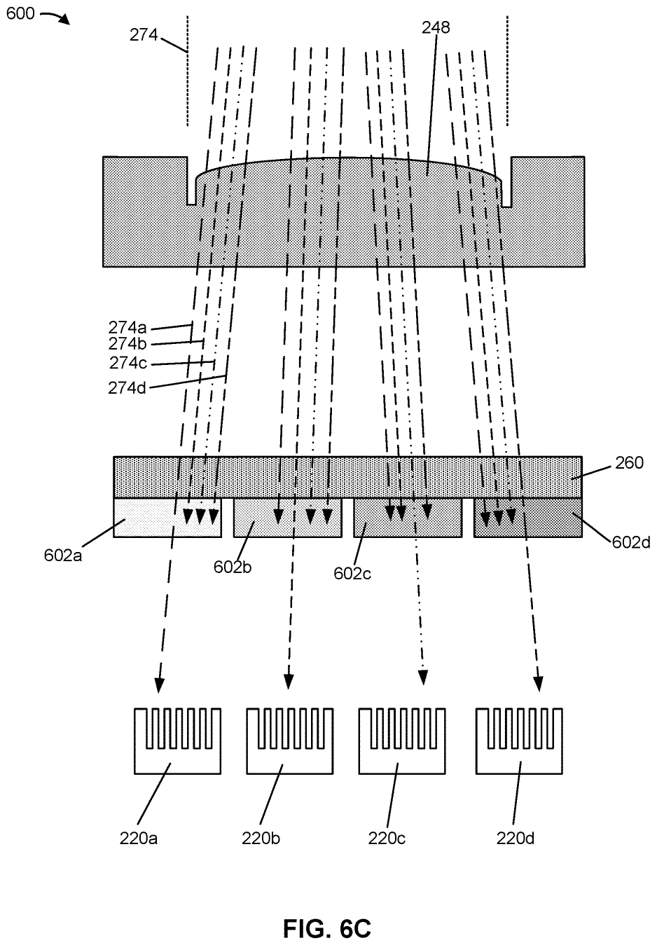

FIGS. 6A-6C are diagrams of an example semiconductor photonics device 600 described herein. The semiconductor photonics device 600 may include a PIC, such as an optical coupling circuit. In general, the semiconductor photonics device 600 may be configured to convert between electrical signals and optical signals for high-bandwidth optical communications.

FIG. 6A illustrates a cross-sectional view of the semiconductor photonics device 600. As shown in FIG. 6A, the semiconductor photonics device 600 may include a similar combination and arrangement of layers and/or structures as the semiconductor photonics device 200 described herein. For example, the semiconductor photonics device 600 may include components 202-272. However, the semiconductor photonics device 600 includes a single micro lens 248 and a single ARC layer 260 for the plurality of grating structures 220a-220d. Moreover, the semiconductor photonics device 600 includes a plurality of color filter layers 602, such as color filter layers 602a-602d. The quantity of color filter layers 602 illustrated in FIG. 6A is an example, and other quantities of color filter layers 602 are within the scope of the present disclosure.

The color filter layers 602a-602d may be included in the oxide fill region 262. The color filter layers 602a-602d may be included under the ARC layer 260. The grating couplers 220, the micro lens 248, the ARC layer 260, and the color filter layers 602 may be vertically aligned in the semiconductor photonics device 600. The micro lens 248 spans the color filter layers 602a-602d.

The color filter layers 602 may be configured to filter particular wavelengths or wavelength ranges of an optical signal. Moreover, each of the color filter layers 602a-602d may be configured to filter a respective wavelength or a respective wavelength range of the optical signal. The materials and/or the properties of the color filter layers 602a-602d may be selected to achieve transmission of a particular wavelength or wavelength range of the optical signal, and to achieve reflection of other wavelengths or other wavelength ranges of the optical signal. In this way, the materials and/or the properties of the color filter layers 602a-602d may be selected to split the optical signal into different wavelengths or different wavelength ranges that are then passed to respective grating couplers 220a-220d. For example, the materials and/or the properties of the color filter layer 602a may be selected to achieve transmission of a first wavelength or a first wavelength range of the optical signal to the grating coupler 220a (and to reflect other wavelengths or other wavelength ranges from being transmitted to the grating coupler 220a), the materials and/or the properties of the color filter layer 602b may be selected to achieve transmission of a second wavelength or a second wavelength range of the optical signal to the grating coupler 220b (and to reflect other wavelengths or other wavelength ranges from being transmitted to the grating coupler 220b), and so on. This enables each of the grating couplers 220a-220d to handle a respective wavelength or a respective wavelength range, which enables the bandwidth of the optical signal to be distributed across the grating couplers 220a-220d as opposed to being handled by a single grating coupler. This enables the semiconductor photonics device 200 to process higher bandwidth signals than a semiconductor photonics device that includes only a single grating coupler.

FIG. 6B illustrates a top-down view of a portion of the semiconductor photonics device 600. As shown in FIG. 6B, the semiconductor photonics device 600 may include a plurality of micro lenses 248, where each micro lens 248 is included over an ARC layer 260, over a plurality of color filter layers 602a-602d, and over a plurality of grating couplers 220a-220d.

FIG. 6C illustrates an example of splitting wavelengths or wavelength ranges of the optical signal 274 using the color filter layers 602. As shown in FIG. 6C, the first wavelength (or the first wavelength range) 274a may be permitted to pass through the color filter layer 602a, and the color filter layer 602a may be configured to filter or reflect other wavelengths or wavelength ranges of the optical signal 274. The second wavelength (or the second wavelength range) 274b may be permitted to pass through the color filter layer 602b, and the color filter layer 602b may be configured to filter or reflect other wavelengths or wavelength ranges of the optical signal 274. The third wavelength (or the third wavelength range) 274c may be permitted to pass through the color filter layer 602c, and the color filter layer 602c may be configured to filter or reflect other wavelengths or wavelength ranges of the optical signal 274. The fourth wavelength (or the fourth wavelength range) 274d may be permitted to pass through the color filter layer 602d, and the color filter layer 602d may be configured to filter or reflect other wavelengths or wavelength ranges of the optical signal 274.

As indicated above, FIGS. 6A-6C are provided as an example. Other examples may differ from what is described with regard to FIGS. 6A-6C.

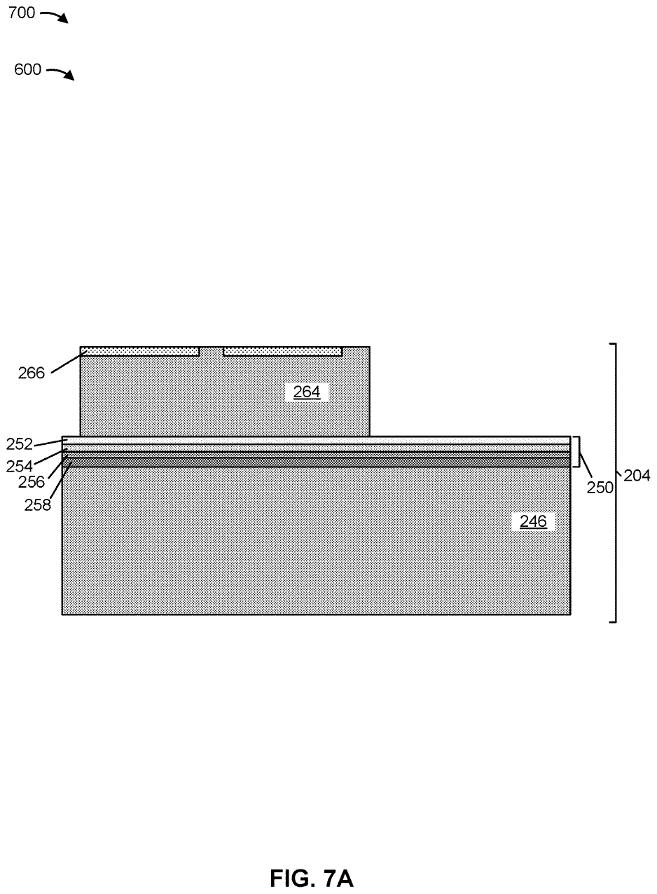

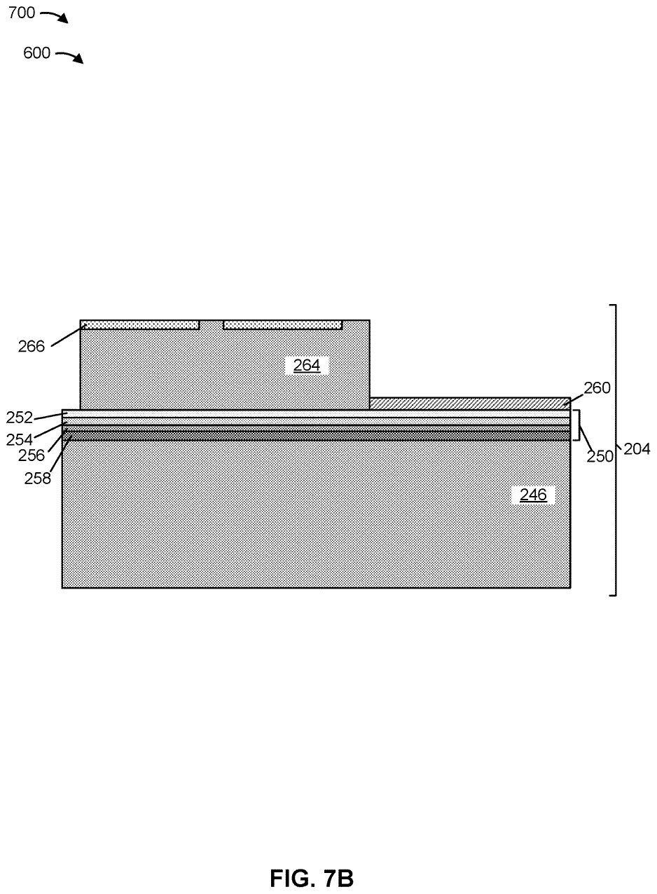

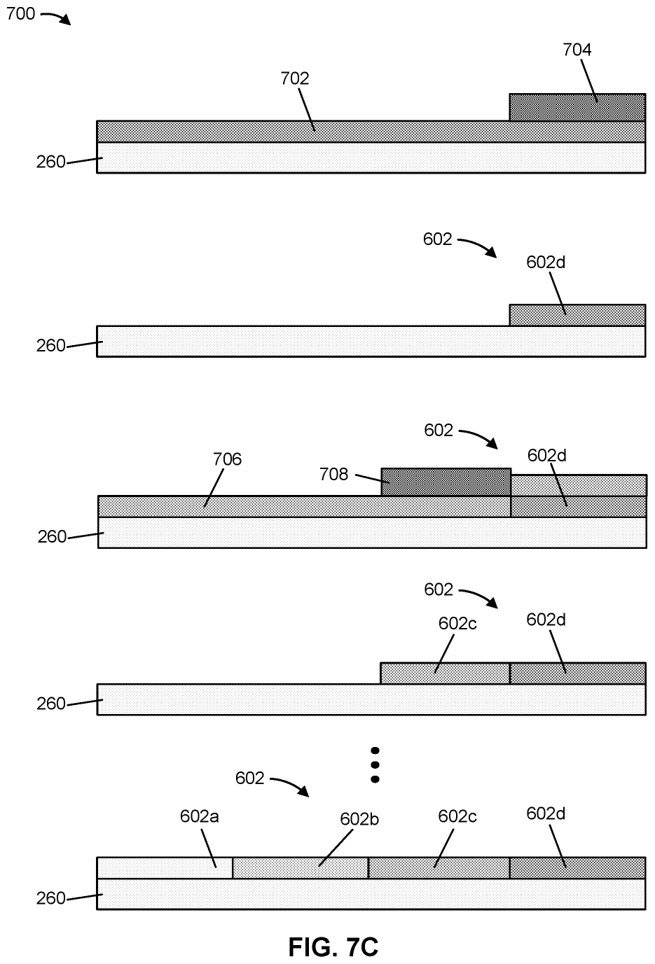

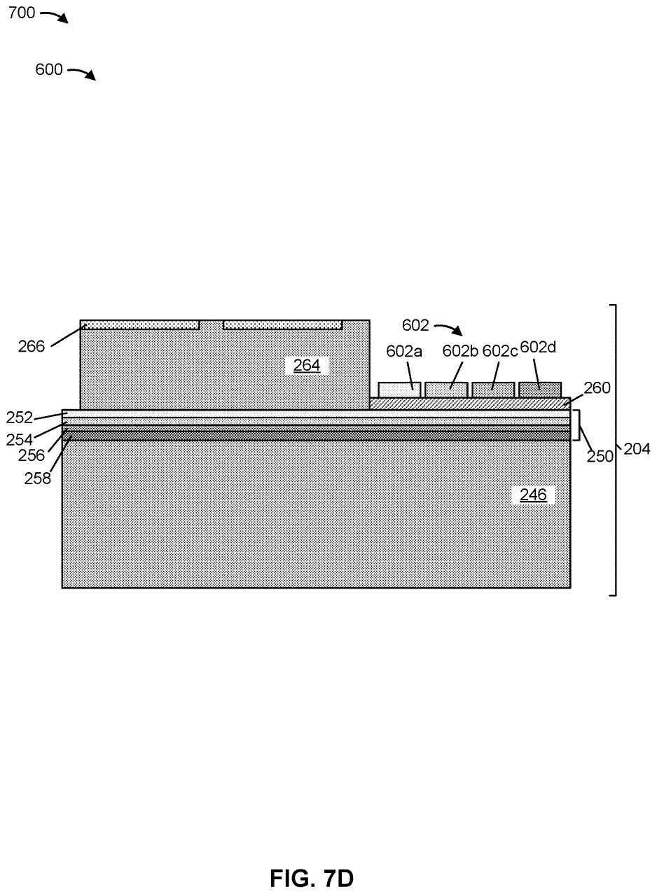

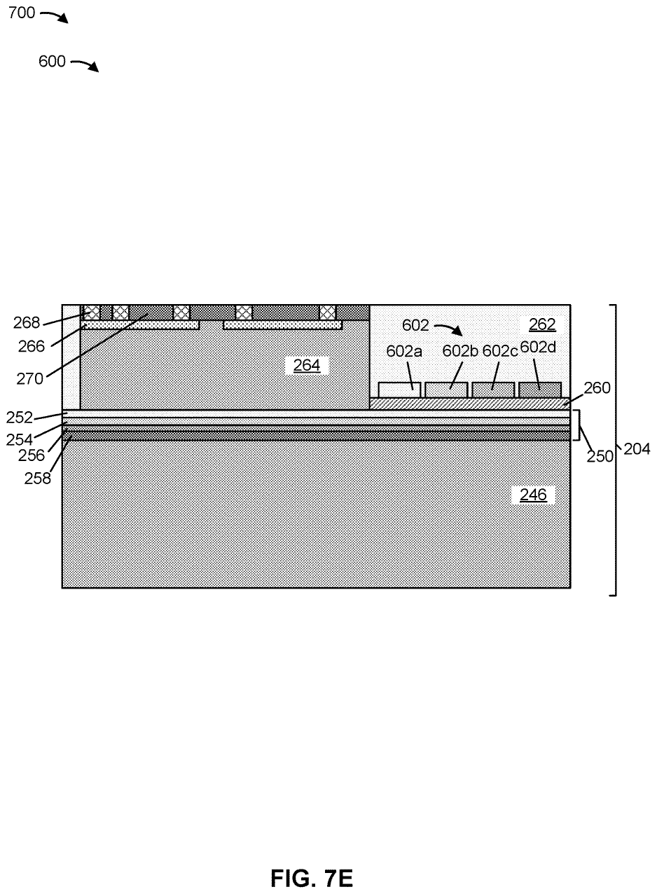

FIGS. 7A-7E are diagrams of an example implementation 700 of forming the second semiconductor die 204 described herein. In particular, the example implementation 700 includes an example of forming the second semiconductor die 204 for use in the semiconductor photonics device 600 described herein. In some implementations, one or more of the semiconductor processing operations described in connection with the example implementation 700 may be performed using one or more of the semiconductor processing tools 102-114 and/or by the wafer/die transport tool 116. In some implementations, one or more of the semiconductor processing operations described in connection with the example implementation 700 may be performed using another semiconductor processing tool.

Turning to FIG. 7A, one or more semiconductor processing operations described in connection with FIGS. 4A-4E may be performed to form components 250-258, 264, and 266 over the semiconductor substrate 246 of the second semiconductor die 204.

As shown in FIG. 7B, the ARC layer 260 is formed over and/or on the layer 252. The deposition tool 102 may be used to deposit the ARC layer 260 in a PVD operation, an ALD operation, a CVD operation, an epitaxy operation, an oxidation operation, another type of deposition operation described in connection with FIG. 1, and/or another suitable deposition operation.

As shown in FIGS. 7C and 7D, the color filter layers 602 may be formed over and/or on the ARC layer 260. As shown in FIG. 7C, forming the color filter layers 602 may include forming a layer 702 of color filter material on the ARC layer 260 (e.g., using a deposition tool 102), forming a photoresist layer 704 on the layer 702 of color filter material (e.g., using a deposition tool 102), forming a pattern in the photoresist layer 704 (e.g., using an exposure tool 104 and a developer tool 106), and removing a portion of the layer 702 of color filter material based on the pattern (e.g., using an etch tool 108) to form a color filter layer 602d. Forming the color filter layers 602 may include forming a layer 706 of color filter material on the ARC layer 260 and adjacent to, and on, the color filter layer 602d (e.g., using a deposition tool 102), forming a photoresist layer 708 on the layer 706 of color filter material (e.g., using a deposition tool 102), forming a pattern in the photoresist layer 408 (e.g., using an exposure tool 104 and a developer tool 106), and removing a portion of the layer 706 of color filter material based on the pattern (e.g., using an etch tool 108) to form a color filter layer 602c. Similar operations may be performed to form the color filter layers 602b and 602a.

As shown in FIG. 7E, one or more semiconductor processing operations described in connection with FIGS. 4H-4J may be performed to form components 262, 268, and 270 of the second semiconductor die 204. In some implementations, the second semiconductor die 204 may be bonded with the first semiconductor die 202, and similar semiconductor processing operations described in connection with FIGS. 5A-5F may be performed to form the semiconductor photonics device 600. In some implementations, the first semiconductor die 202 may be formed using semiconductor processing techniques described in connection with FIGS. 3A-3H.

As indicated above, FIGS. 7A-7E are provided as an example. Other examples may differ from what is described with regard to FIGS. 7A-7E.

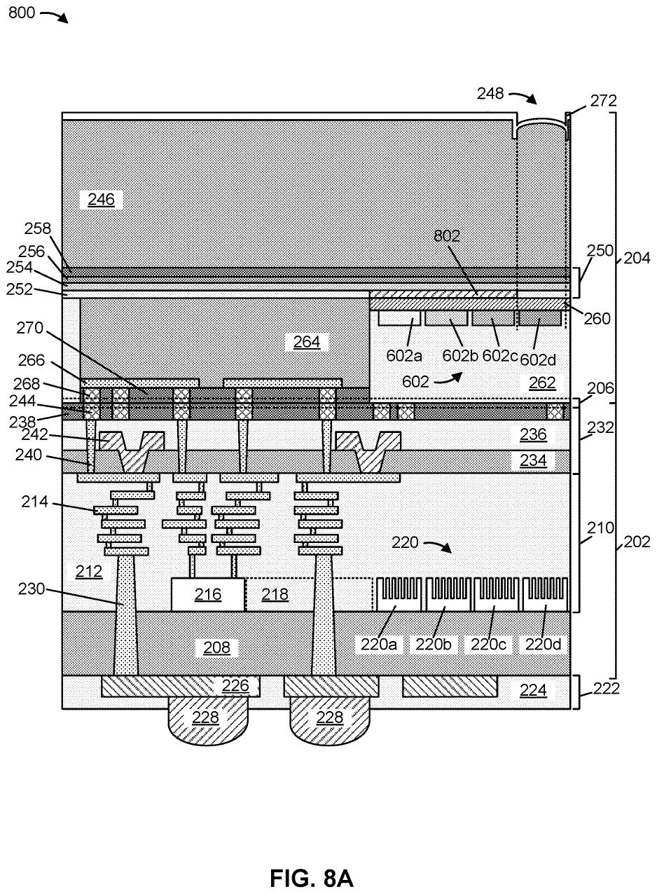

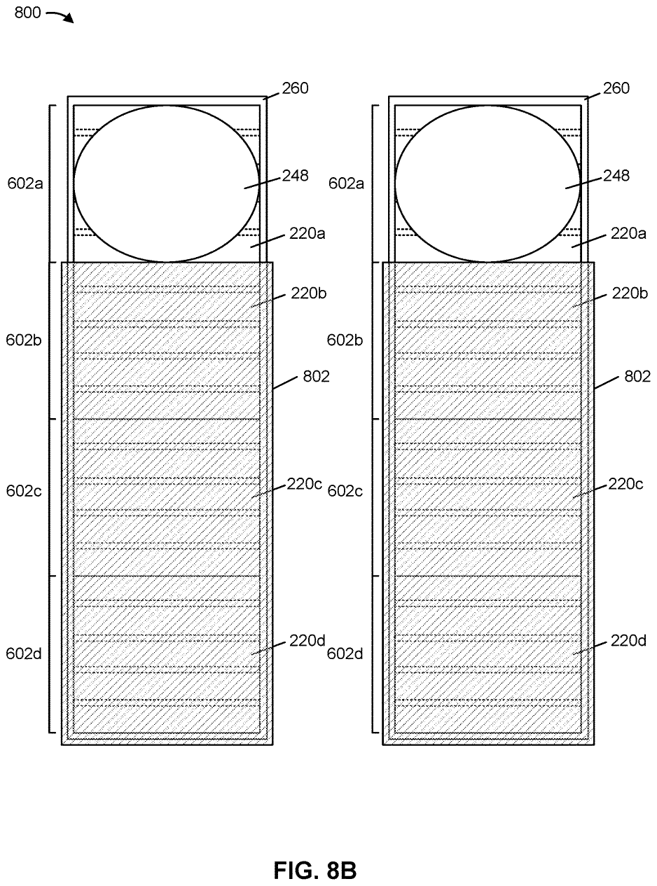

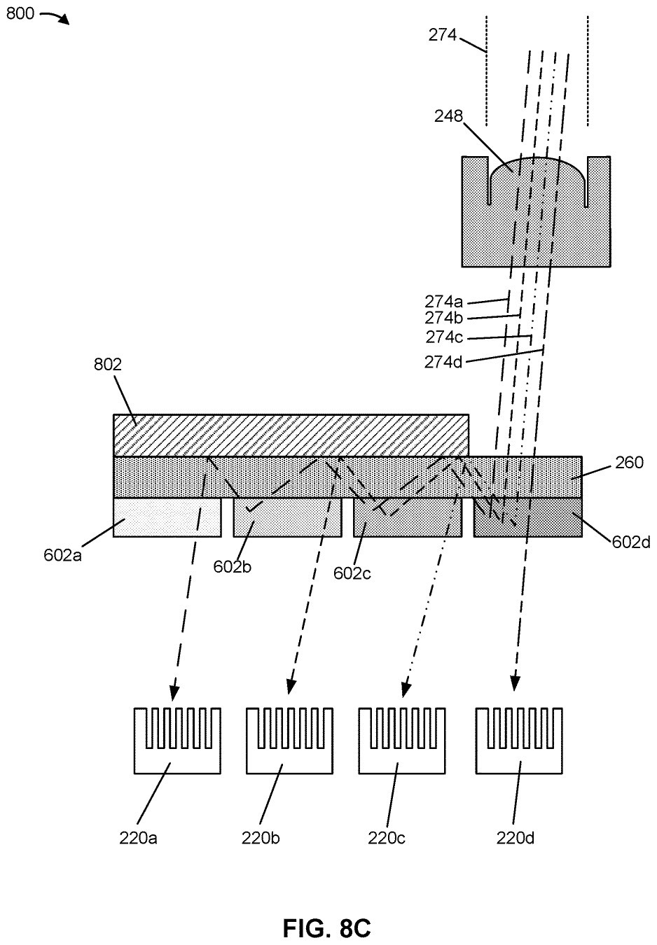

FIGS. 8A-8C are diagrams of an example semiconductor photonics device 800 described herein. The semiconductor photonics device 800 may include a PIC, such as an optical coupling circuit. In general, the semiconductor photonics device 800 may be configured to convert between electrical signals and optical signals for high-bandwidth optical communications.

FIG. 8A illustrates a cross-sectional view of the semiconductor photonics device 800. As shown in FIG. 8A, the semiconductor photonics device 800 may include a similar combination and arrangement of layers and/or structures as the semiconductor photonics device 600 described herein. For example, the semiconductor photonics device 800 may include components 202-272 and 602. However, the semiconductor photonics device 800 includes a single micro lens 248 that is located or positioned directly above and/or over a single color filter layer 602d and directly above and/or over a single grating coupler 220d. Moreover, the semiconductor photonics device 800 includes a reflector layer 802 directly over the color filter layers 602a-602c. In other words, the micro lens 248 may be included over the color filter layer 602d and not over the color filter layers 602a-602c, whereas the reflector layer 802 may be included over the color filter layers 602a-602c and not over the color filter layer 602d. A first portion of the ARC layer 260 may be included under the reflector layer 802, and a second portion of the ARC layer 260 may extend laterally outward from the reflector layer 802 and over the color filter layer 602d.

The reflector layer 802 may include a highly reflective material such as a metal material. Examples include aluminum (Al), tungsten (W), titanium (Ti), copper (Cu), ruthenium (Ru), and/or cobalt (Co), among other examples. The reflector layer 802 may be included in a recess in layer 252, or may be included in another layer above the ARC layer 260. The reflector layer 802 is configured to reflect a portion of an optical signal toward the color filter layers 602a-602c. The portion of the optical signal corresponds to a portion of the optical signal that is reflected off of the color filter layer 602d. The various wavelength components of the optical signal reflect off of the reflector layer 802 and the color filter layers 602a-602c until passing through a color filter layer 602 that is configured to pass each particular wavelength component.

FIG. 8B illustrates a top-down view of a portion of the semiconductor photonics device 800. As shown in FIG. 8B, the semiconductor photonics device 800 may include a plurality of micro lenses 248, where each micro lens 248 is included over a single color filter layer 602. The reflector layer 802 is omitted from the color filter layer 602 over which the micro lens 248 is positioned. This enables an optical signal to pass from the micro lens 248 to the color filter layer 602 under the micro lens 248. The reflector layer 802 would otherwise block the optical signal from reaching the color filter layer 602 under the micro lens 248 if the reflector layer 802 were included between the micro lens 248 and the color filter layer 602 under the micro lens 248.

FIG. 8C illustrates an example of splitting wavelengths or wavelength ranges of the optical signal 274 using the color filter layers 602 and the reflector layer 802. As shown in FIG. 8C, the optical signal 274 enters the semiconductor photonics device 800 through the micro lens 248 over the color filter layer 602d. The fourth wavelength (or the fourth wavelength range) 274d may be permitted to pass through the color filter layer 602d, and the color filter layer 602d may be configured to filter or reflect other wavelengths or wavelength ranges of the optical signal 274. The reflected wavelengths (or wavelength ranges) propagate back through the ARC layer 260 and reflect off of the reflector layer 802 toward the color filter layer 602c. The third wavelength (or the third wavelength range) 274c may be permitted to pass through the color filter layer 602c, and the color filter layer 602c may be configured to filter or reflect other wavelengths or wavelength ranges of the optical signal 274. The reflected wavelengths (or wavelength ranges) propagate back through the ARC layer 260 and reflect off of the reflector layer 802 toward the color filter layer 602b. The second wavelength (or the second wavelength range) 274b may be permitted to pass through the color filter layer 602b, and the color filter layer 602b may be configured to filter or reflect other wavelengths or wavelength ranges of the optical signal 274. The reflected wavelengths (or wavelength ranges) propagate back through the ARC layer 260 and reflect off of the reflector layer 802 toward the color filter layer 602a. The first wavelength (or the first wavelength range) 274a may be permitted to pass through the color filter layer 602a, and the color filter layer 602a may be configured to filter or reflect other wavelengths or wavelength ranges of the optical signal 274.

As indicated above, FIGS. 8A-8C are provided as an example. Other examples may differ from what is described with regard to FIGS. 8A-8C.

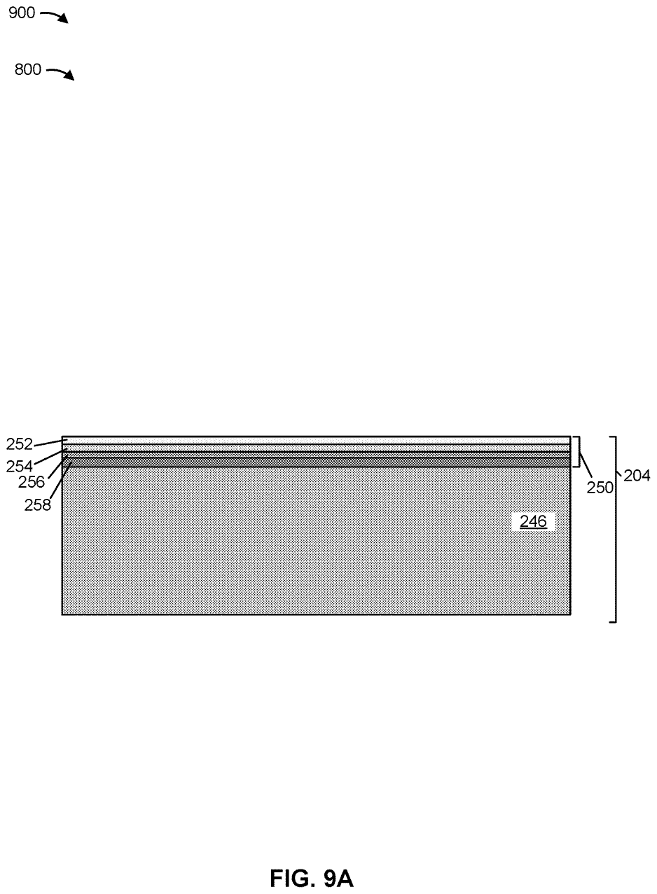

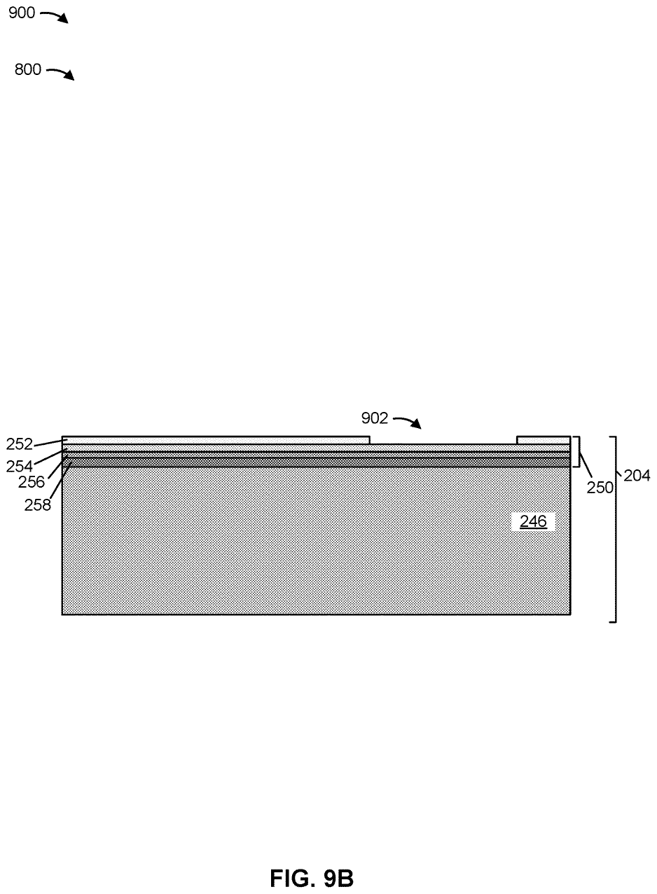

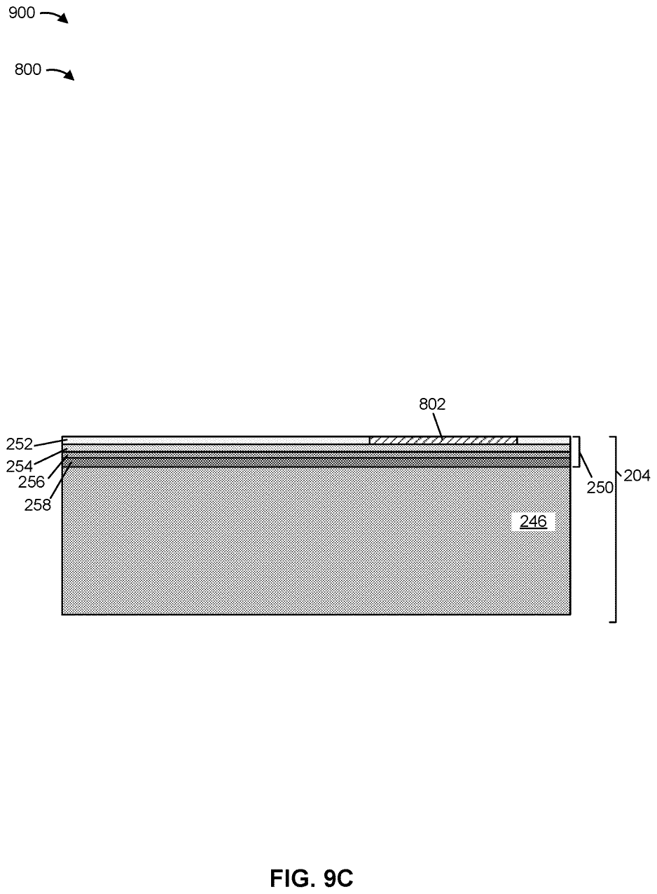

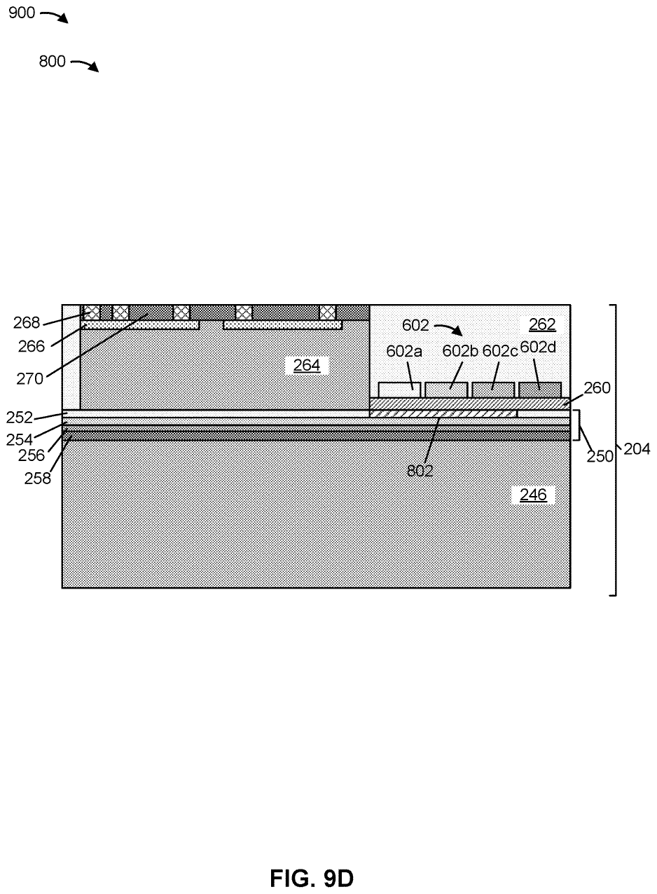

FIGS. 9A-9D are diagrams of an example implementation 900 of forming the second semiconductor die 204 described herein. In particular, the example implementation 900 includes an example of forming the second semiconductor die 204 for use in the semiconductor photonics device 800 described herein. In some implementations, one or more of the semiconductor processing operations described in connection with the example implementation 900 may be performed using one or more of the semiconductor processing tools 102-114 and/or by the wafer/die transport tool 116. In some implementations, one or more of the semiconductor processing operations described in connection with the example implementation 900 may be performed using another semiconductor processing tool.

Turning to FIG. 9A, one or more semiconductor processing operations described in connection with FIGS. 4A and 4B may be performed to form components 250-258 over the semiconductor substrate 246 of the second semiconductor die 204.

As shown in FIG. 9B, a recess 902 may be formed in the layer 252. In some implementations, a pattern in a photoresist layer is used to etch the layer 252 to form the recess 902. In these implementations, a deposition tool 102 may be used to form the photoresist layer on the layer 252. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the layer 252 based on the pattern to form the recess 902 in the layer 252. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the layer 252 based on a pattern.

As shown in FIG. 9C, the reflector layer 802 may be formed in the recess 902 in the layer 252. A deposition tool 102 and/or a plating tool 112 may be used to deposit the reflector layer 802 in a CVD operation, a PVD operation, an ALD operation, an electroplating operation, another deposition operation described above in connection with FIG. 1, and/or another suitable deposition operation. In some implementations, a seed layer is first deposited, and the reflector layer 802 is deposited on the seed layer. In some implementations, a planarization tool 110 may be used to planarize the reflector layer 802 after the reflector layer 802 is deposited.

As shown in FIG. 9D, one or more semiconductor processing operations described in connection with FIGS. 4C-4J and/or 7A-7E may be performed to form components 262-270 and and/or 602 of the second semiconductor die 204. In some implementations, the second semiconductor die 204 may be bonded with the first semiconductor die 202, and similar semiconductor processing operations described in connection with FIGS. 5A-5F may be performed to form the semiconductor photonics device 800. In some implementations, the first semiconductor die 202 may be formed using semiconductor processing techniques described in connection with FIGS. 3A-3H.

As indicated above, FIGS. 9A-9D are provided as an example. Other examples may differ from what is described with regard to FIGS. 9A-9D.

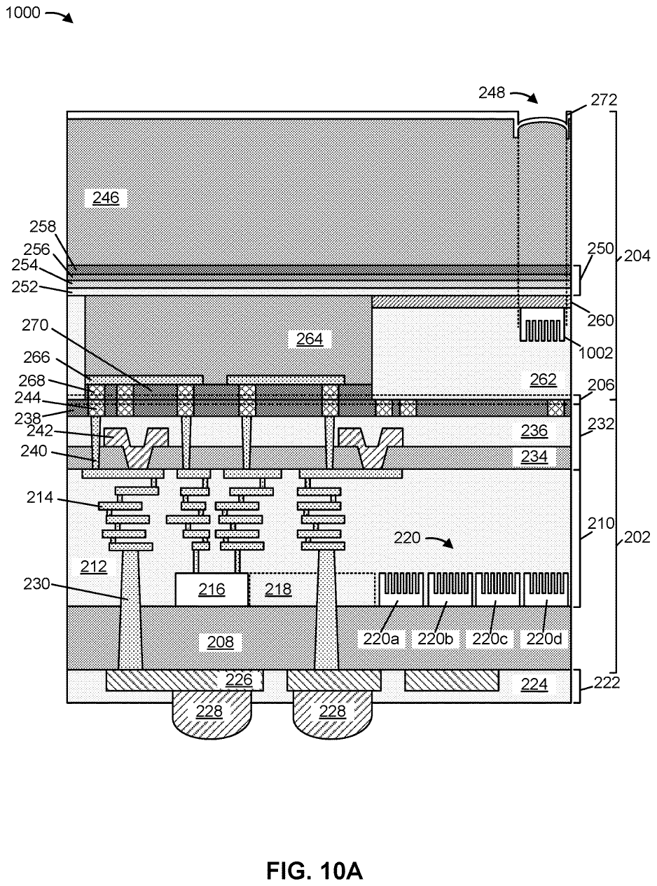

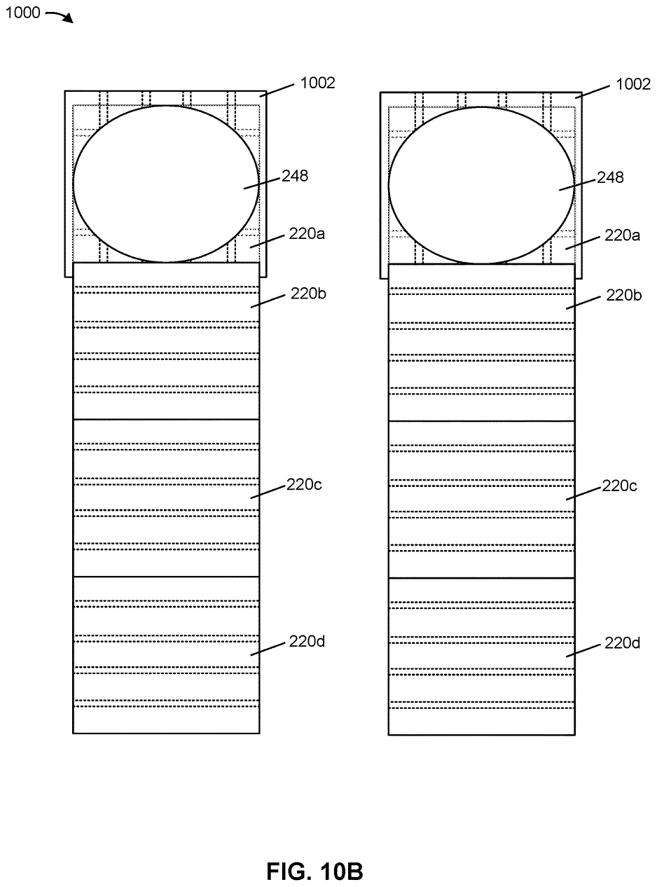

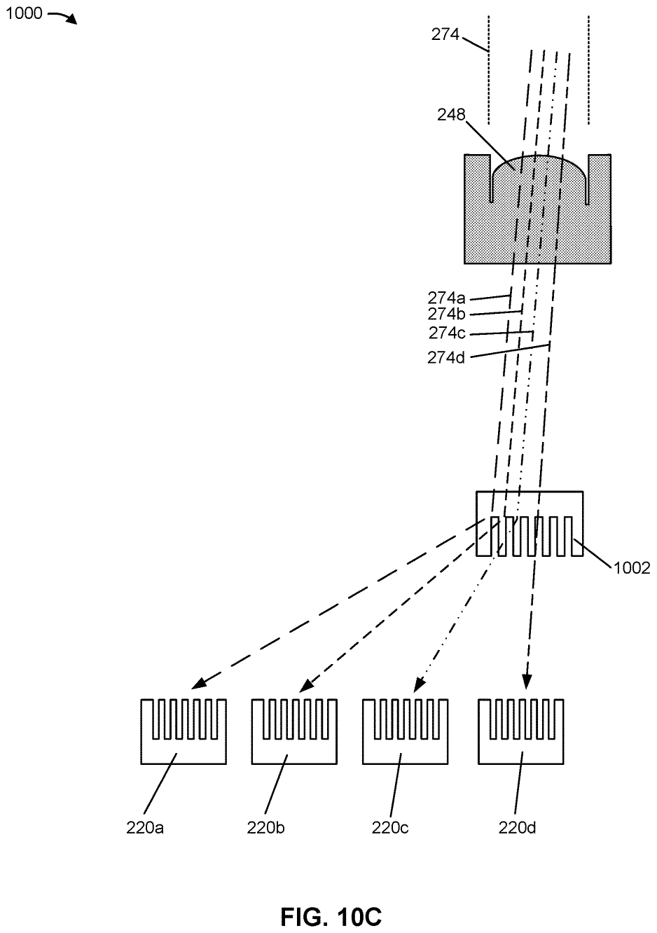

FIGS. 10A-10C are diagrams of an example semiconductor photonics device 1000 described herein. The semiconductor photonics device 1000 may include a PIC, such as an optical coupling circuit. In general, the semiconductor photonics device 1000 may be configured to convert between electrical signals and optical signals for high-bandwidth optical communications.

FIG. 10A illustrates a cross-sectional view of the semiconductor photonics device 1000. As shown in FIG. 10A, the semiconductor photonics device 1000 may include a similar combination and arrangement of layers and/or structures as the semiconductor photonics device 600 described herein. For example, the semiconductor photonics device 1000 may include components 202-272. However, the color filter layers 602 are omitted from the semiconductor photonics device 1000. Moreover, the semiconductor photonics device 1000 includes a single micro lens 248 that is located or positioned directly above and/or over a grating structure 1002 located in the oxide fill region 262. In some implementations, the grating structure 1002 may be included in another region of the second semiconductor die 204, such as in the semiconductor substrate 246. Alternatively, the grating structure 1002 may be included in the first semiconductor die 202 above the grating coupler 220d.

The grating structure 1002 is configured to split an optical signal into different wavelength components. The grating structure 1002 may include a semiconductor structure, a dielectric structure, and/or another type of structure that includes a plurality of gratings. The pitch of the gratings of the grating structure 1002 may be included in a range of approximately 300 nanometers to approximately 1000 nanometers. However, other values for the range are within the scope of the present disclosure. The grating structure 1002 may have sections that each have a different grating pitch to enable the sections to each split out different wavelengths (or wavelength ranges) of the optical signal. In some implementations, the grating structure 1002 may be configured to operate in a range of approximately 1% duty cycle to approximately 99% duty cycle. However, other values for the range are within the scope of the present disclosure.

FIG. 10B illustrates a top-down view of a portion of the semiconductor photonics device 1000. As shown in FIG. 10B, the semiconductor photonics device 1000 may include a plurality of micro lenses 248, where each micro lens 248 is included over a single grating coupler 220 and over a grating structure 1002.

FIG. 10C illustrates an example of splitting wavelengths or wavelength ranges of the optical signal 274 using the grating structure 1002. As shown in FIG. 10C, the optical signal 274 enters the semiconductor photonics device 1000 through the micro lens 248 over the grating structure 1002. The grating structure 1002 splits the optical signal 274 into the first wavelength (or the first wavelength range) 274a, the second wavelength (or the second wavelength range) 274b, the third wavelength (or the third wavelength range) 274c, and the fourth wavelength (or the fourth wavelength range) 274d. The grating structure 1002 directs the first wavelength (or the first wavelength range) 274a to the grating coupler 220a. The grating structure 1002 directs the second wavelength (or the second wavelength range) 274b to the grating coupler 220b. The grating structure 1002 directs the third wavelength (or the third wavelength range) 274c to the grating coupler 220c. The grating structure 1002 directs the fourth wavelength (or the fourth wavelength range) 274d to the grating coupler 220d.

As indicated above, FIGS. 10A-10C are provided as an example. Other examples may differ from what is described with regard to FIGS. 10-10C.

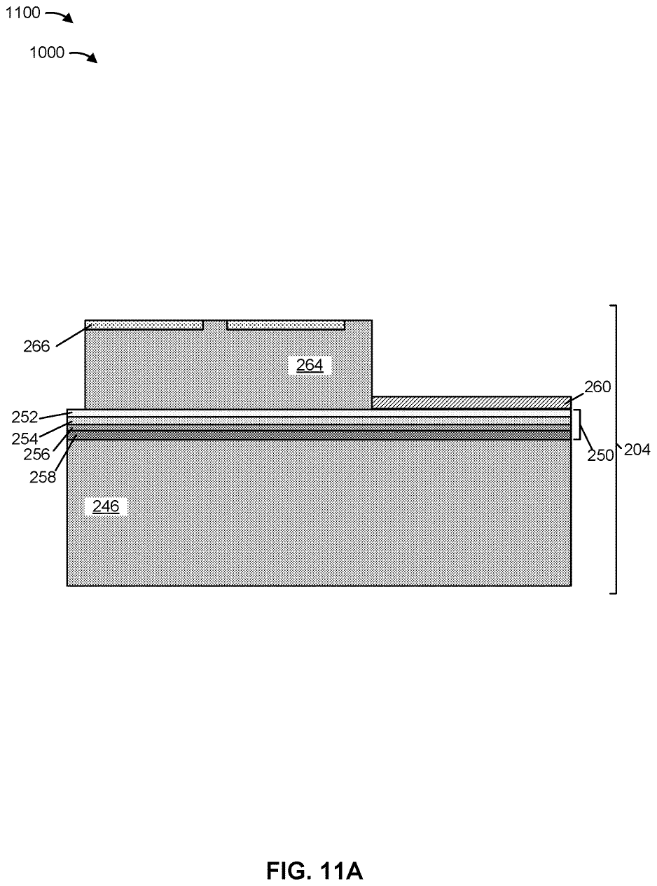

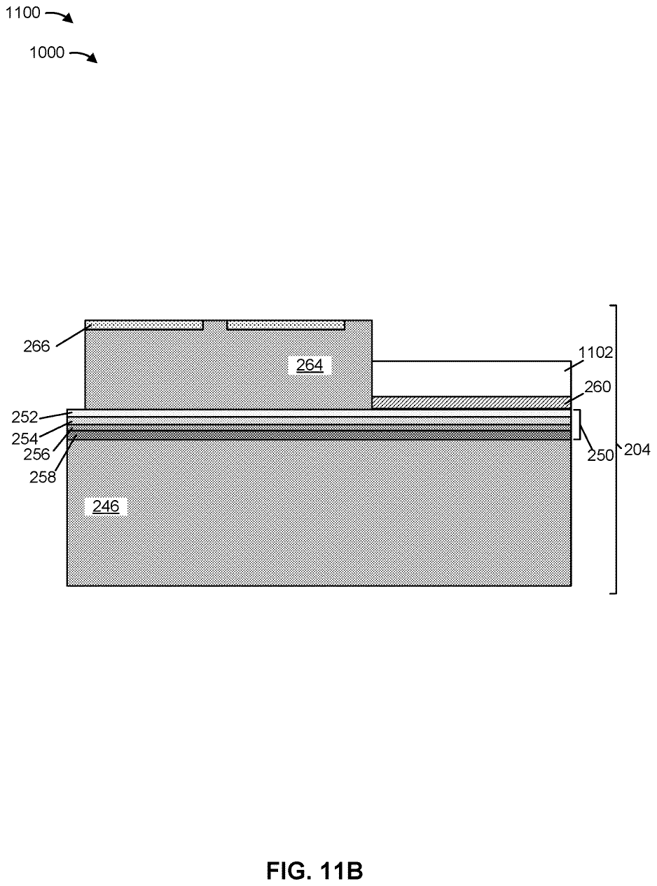

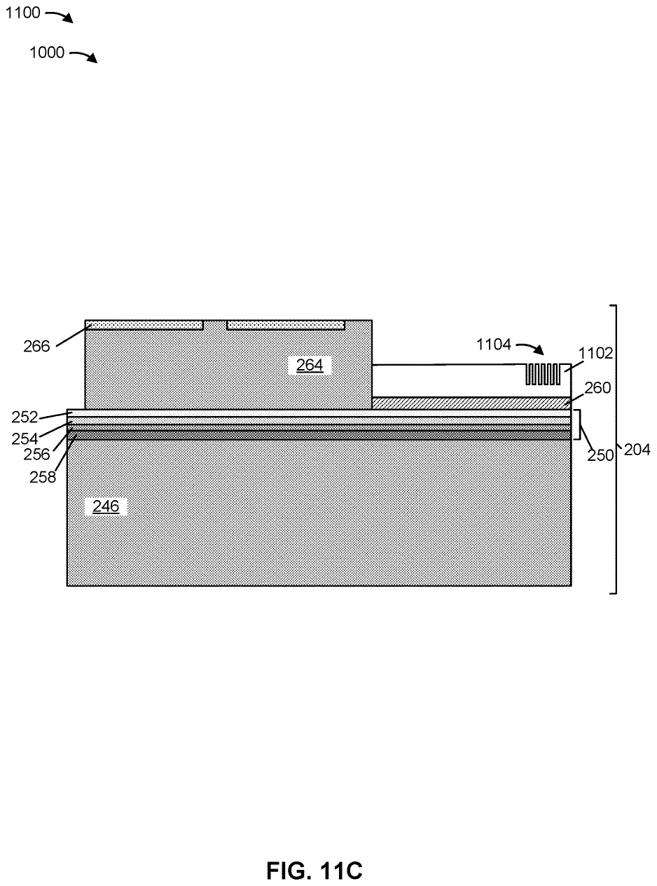

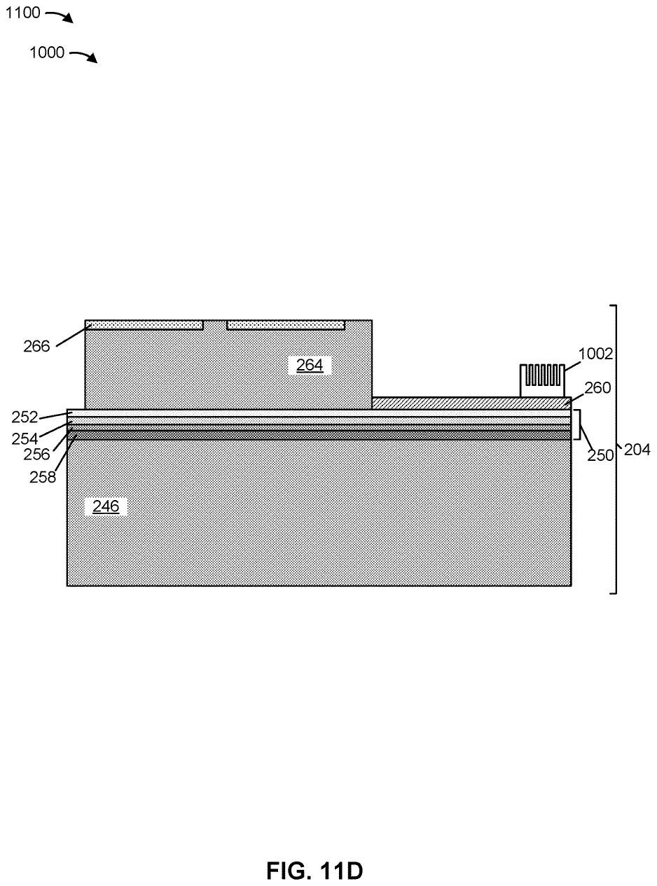

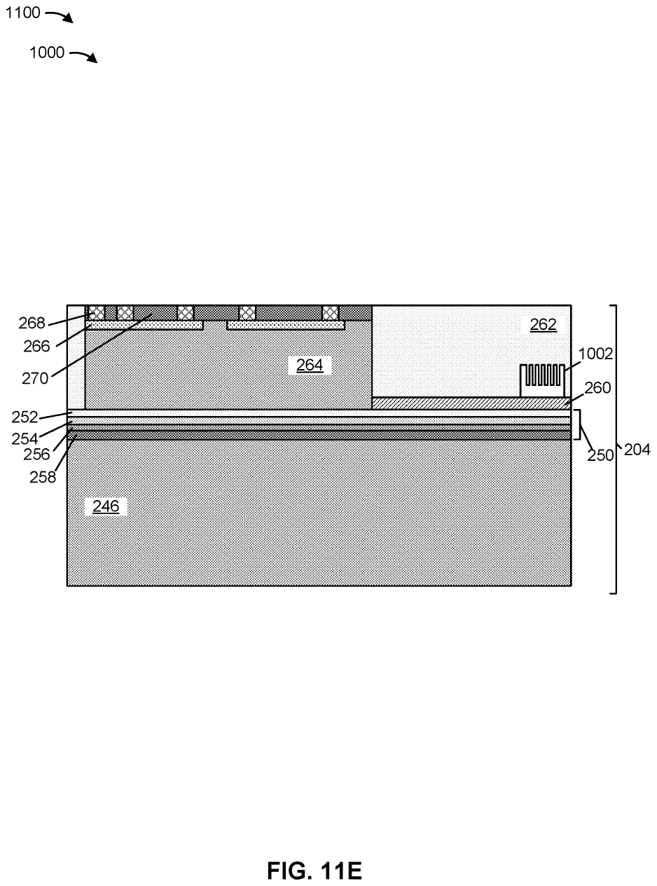

FIGS. 11A-11E are diagrams of an example implementation 1100 of forming the second semiconductor die 204 described herein. In particular, the example implementation 1100 includes an example of forming the second semiconductor die 204 for use in the semiconductor photonics device 1000 described herein. In some implementations, one or more of the semiconductor processing operations described in connection with the example implementation 1100 may be performed using one or more of the semiconductor processing tools 102-114 and/or by the wafer/die transport tool 116. In some implementations, one or more of the semiconductor processing operations described in connection with the example implementation 1100 may be performed using another semiconductor processing tool.

Turning to FIG. 11A, one or more semiconductor processing operations described in connection with FIGS. 4A-4E and/or 7B may be performed to form components 250-260, 264, and 266 over the semiconductor substrate 246 of the second semiconductor die 204.

As shown in FIG. 11B, a layer 1102 of grating material may be formed over and/or on the ARC layer 260. A deposition tool 102 may be used to deposit the layer 1102 of grating material in a PVD operation, an ALD operation, a CVD operation, an epitaxy operation, an oxidation operation, another type of deposition operation described in connection with FIG. 1, and/or another suitable deposition operation.

As shown in FIG. 11C, gratings 1104 may be formed in the layer 1102 of grating material. In some implementations, a pattern in a photoresist layer is used to etch the layer 1102 of grating material to form the gratings 1104. In these implementations, a deposition tool 102 may be used to form the photoresist layer on the layer 1102 of grating material. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the layer 1102 of grating material based on the pattern to form the gratings 1104 in the layer 1102 of grating material. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the layer 1102 of grating material based on a pattern.

As shown in FIG. 11D, additional portions of the layer 1102 of grating material may be removed to form the grating structure 1002 over and/or on the ARC layer 260. In some implementations, a pattern in a photoresist layer is used to etch the layer 1102 of grating material to form the grating structure 1002. In these implementations, a deposition tool 102 may be used to form the photoresist layer on the layer 1102 of grating material. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the layer 1102 of grating material based on the pattern to form the grating structure 1002. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the layer 1102 of grating material based on a pattern.

As shown in FIG. 11E, one or more semiconductor processing operations described in connection with FIGS. 4H-4J may be performed to form components 262 and 266-270 of the second semiconductor die 204. In some implementations, the second semiconductor die 204 may be bonded with the first semiconductor die 202, and similar semiconductor processing operations described in connection with FIGS. 5A-5F may be performed to form the semiconductor photonics device 1000. In some implementations, the first semiconductor die 202 may be formed using semiconductor processing techniques described in connection with FIGS. 3A-3H.

As indicated above, FIGS. 11A-11E are provided as an example. Other examples may differ from what is described with regard to FIGS. 11A-11E.

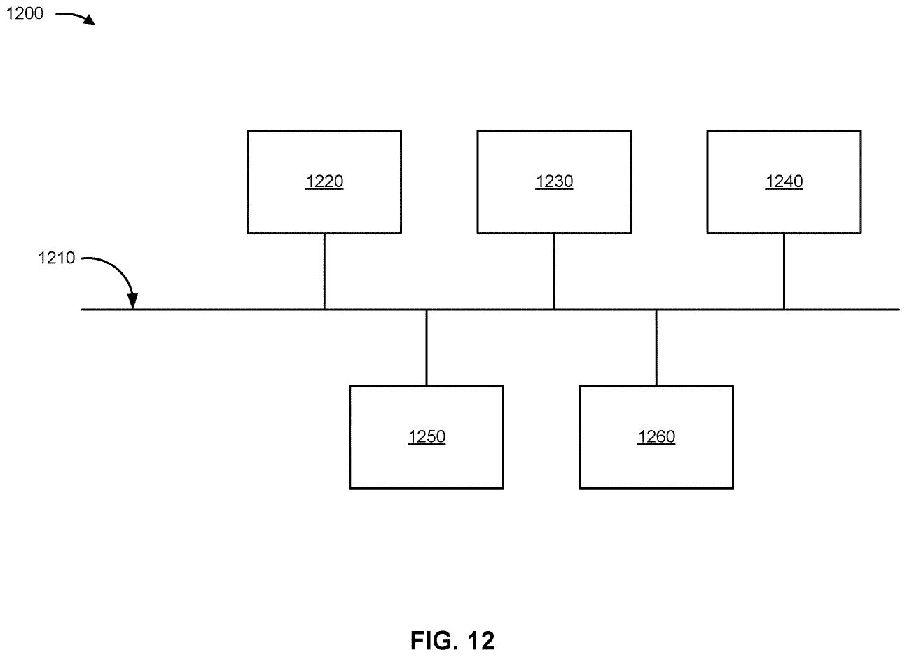

FIG. 12 is a diagram of example components of a device 1200 described herein. In some implementations, one or more of the semiconductor processing tools 102-114 and/or the wafer/die transport tool 116 may include one or more devices 1200 and/or one or more components of the device 1200. As shown in FIG. 12, the device 1200 may include a bus 1210, a processor 1220, a memory 1230, an input component 1240, an output component 1250, and/or a communication component 1260.

The bus 1210 may include one or more components that enable wired and/or wireless communication among the components of the device 1200. The bus 1210 may couple together two or more components of FIG. 12, such as via operative coupling, communicative coupling, electronic coupling, and/or electric coupling. For example, the bus 1210 may include an electrical connection (e.g., a wire, a trace, and/or a lead) and/or a wireless bus. The processor 1220 may include a central processing unit, a graphics processing unit, a microprocessor, a controller, a microcontroller, a digital signal processor, a field-programmable gate array, an application-specific integrated circuit, and/or another type of processing component. The processor 1220 may be implemented in hardware, firmware, or a combination of hardware and software. In some implementations, the processor 1220 may include one or more processors capable of being programmed to perform one or more operations or processes described elsewhere herein.

The memory 1230 may include volatile and/or nonvolatile memory. For example, the memory 1230 may include random access memory (RAM), read only memory (ROM), a hard disk drive, and/or another type of memory (e.g., a flash memory, a magnetic memory, and/or an optical memory). The memory 1230 may include internal memory (e.g., RAM, ROM, or a hard disk drive) and/or removable memory (e.g., removable via a universal serial bus connection). The memory 1230 may be a non-transitory computer-readable medium. The memory 1230 may store information, one or more instructions, and/or software (e.g., one or more software applications) related to the operation of the device 1200. In some implementations, the memory 1230 may include one or more memories that are coupled (e.g., communicatively coupled) to one or more processors (e.g., processor 1220), such as via the bus 1210. Communicative coupling between a processor 1220 and a memory 1230 may enable the processor 1220 to read and/or process information stored in the memory 1230 and/or to store information in the memory 1230.

The input component 1240 may enable the device 1200 to receive input, such as user input and/or sensed input. For example, the input component 1240 may include a touch screen, a keyboard, a keypad, a mouse, a button, a microphone, a switch, a sensor, a global positioning system sensor, a global navigation satellite system sensor, an accelerometer, a gyroscope, and/or an actuator. The output component 1250 may enable the device 1200 to provide output, such as via a display, a speaker, and/or a light-emitting diode. The communication component 1260 may enable the device 1200 to communicate with other devices via a wired connection and/or a wireless connection. For example, the communication component 1260 may include a receiver, a transmitter, a transceiver, a modem, a network interface card, and/or an antenna.

The device 1200 may perform one or more operations or processes described herein. For example, a non-transitory computer-readable medium (e.g., memory 1230) may store a set of instructions (e.g., one or more instructions or code) for execution by the processor 1220. The processor 1220 may execute the set of instructions to perform one or more operations or processes described herein. In some implementations, execution of the set of instructions, by one or more processors 1220, causes the one or more processors 1220 and/or the device 1200 to perform one or more operations or processes described herein. In some implementations, hardwired circuitry may be used instead of or in combination with the instructions to perform one or more operations or processes described herein. Additionally, or alternatively, the processor 1220 may be configured to perform one or more operations or processes described herein. Thus, implementations described herein are not limited to any specific combination of hardware circuitry and software.

The number and arrangement of components shown in FIG. 12 are provided as an example. The device 1200 may include additional components, fewer components, different components, or differently arranged components than those shown in FIG. 12. Additionally, or alternatively, a set of components (e.g., one or more components) of the device 1200 may perform one or more functions described as being performed by another set of components of the device 1200.

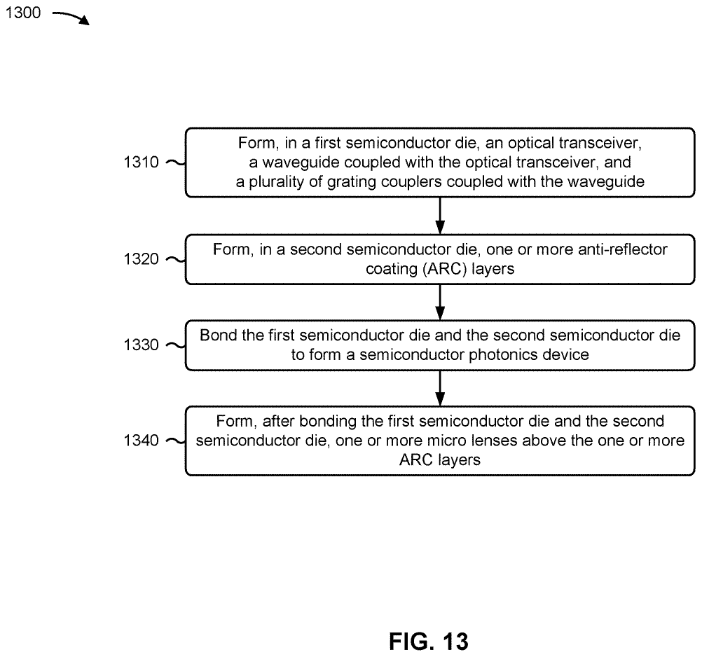

FIG. 13 is a flowchart of an example process 1300 associated with forming a semiconductor photonics device described herein. In some implementations, one or more process blocks of FIG. 13 are performed using one or more semiconductor processing tools (e.g., one or more of the semiconductor processing tools 102-114). Additionally, or alternatively, one or more process blocks of FIG. 13 may be performed using one or more components of device 1200, such as processor 1220, memory 1230, input component 1240, output component 1250, and/or communication component 1260.

As shown in FIG. 13, process 1300 may include forming, in a first semiconductor die, an optical transceiver, a waveguide coupled with the optical transceiver, and a plurality of grating couplers coupled with the waveguide (block 1310). For example, one or more of the semiconductor processing tools 102-114 may be used to form, in a first semiconductor die 202, an optical transceiver 216, a waveguide 218 coupled with the optical transceiver 216, and a plurality of grating couplers 220 (e.g., one or more grating couplers 220a-220d) coupled with the waveguide 218, as described herein.

As further shown in FIG. 13, process 1300 may include forming, in a second semiconductor die, one or more ARC layers (block 1320). For example, one or more of the semiconductor processing tools 102-114 may be used to form, in a second semiconductor die 204, one or more ARC layers 260 (e.g., one or more ARC layers 260a-260d), as described herein.

As further shown in FIG. 13, process 1300 may include bonding the first semiconductor die and the second semiconductor die to form a semiconductor photonics device (block 1330). For example, one or more of the semiconductor processing tools 102-114 may be used to bond the first semiconductor die 202 and the second semiconductor die 204 to form a semiconductor photonics device 200, as described herein. In some implementations, the one or more ARC layers 260 are located over at least a subset of the plurality of grating couplers 220 after the first semiconductor die 202 and the second semiconductor die 204 are bonded.

As further shown in FIG. 13, process 1300 may include forming, after bonding the first semiconductor die and the second semiconductor die, one or more micro lenses above the one or more ARC layers (block 1340). For example, one or more of the semiconductor processing tools 102-114 may be used to form, after bonding the first semiconductor die 202 and the second semiconductor die 204, one or more micro lenses 248 (e.g., one or more micro lenses 248a-248d) above the one or more ARC layers 260, as described herein.

Process 1300 may include additional implementations, such as any single implementation or any combination of implementations described below and/or in connection with one or more other processes described elsewhere herein.

In a first implementation, process 1300 includes forming, in the second semiconductor die 204 prior to bonding the first semiconductor die 202 and the second semiconductor die 204, a grating structure 1002 above the one or more ARC layers 260.

In a second implementation, alone or in combination with the first implementation, forming the one or more micro lenses 248 includes forming the one or more micro lenses 248 above the grating structure 1002.

In a third implementation, alone or in combination with one or more of the first and second implementations, the grating structure 1002 is located above one of the plurality of grating couplers 220 after the first semiconductor die 202 and the second semiconductor die 204 are bonded.

In a fourth implementation, alone or in combination with one or more of the first through third implementations, process 1300 includes forming, in the second semiconductor die 204 prior to bonding the first semiconductor die 202 and the second semiconductor die 204, a reflector layer 802, where forming the one or more ARC layers 260 includes forming the one or more ARC layers 260 above the reflector layer 802.

In a fifth implementation, alone or in combination with one or more of the first through fourth implementations, a first portion of the one or more ARC layers 260 is located on the reflector layer 802, and a second portion of the one or more ARC layers 260 extends laterally outward from the reflector layer 802.

In a sixth implementation, alone or in combination with one or more of the first through fifth implementations, process 1300 includes forming, in the second semiconductor die 204 prior to bonding the first semiconductor die 202 and the second semiconductor die 204, a plurality of color filter layers 602 (e.g., color filter layers 602a-602d) over the one or more ARC layers 260.

Although FIG. 13 shows example blocks of process 1300, in some implementations, process 1300 includes additional blocks, fewer blocks, different blocks, or differently arranged blocks than those depicted in FIG. 13. Additionally, or alternatively, two or more of the blocks of process 1300 may be performed in parallel.

In this way, a semiconductor photonics device includes a plurality of grating couplers, each configured to couple a particular wavelength (or wavelength range) of an optical signal to a waveguide of the semiconductor photonics device. In some implementations, various implementations of optical signal splitters or filters described herein enable respective wavelengths (or respective wavelength ranges) to be passed to each of the grating couplers (while filtering out other wavelengths or other wavelength ranges), thereby enabling the grating couplers to each handle a respective wavelength (or respective wavelength range). This enables multiple wavelengths (or multiple wavelength ranges) to be distributed across multiple grating couplers, which may increase the bandwidth of the semiconductor photonics device relative to a semiconductor photonics device that includes only a single grating coupler.

As described in greater detail above, some implementations described herein provide a semiconductor photonics device. The semiconductor photonics device includes an optical transceiver. The semiconductor photonics device includes a waveguide coupled with the optical transceiver. The semiconductor photonics device includes a plurality of grating couplers coupled with the waveguide. The semiconductor photonics device includes a plurality of ARC layers, where each ARC layer of the plurality of ARC layers is above a respective one of the plurality of grating couplers. The semiconductor photonics device includes a plurality of micro lenses, where each micro lens of the plurality of micro lenses is above a respective one of the plurality of ARC layers.

As described in greater detail above, some implementations described herein provide a semiconductor photonics device. The semiconductor photonics device includes an optical transceiver. The semiconductor photonics device includes a waveguide coupled with the optical transceiver. The semiconductor photonics device includes a plurality of grating couplers coupled with the waveguide. The semiconductor photonics device includes a plurality of color filter layers, where each color filter layer of the plurality of color filter layers is above a respective one of the plurality of grating couplers. The semiconductor photonics device includes an ARC layer above the plurality of color filter layers. The semiconductor photonics device includes a micro lens above one or more of the color filter layers.

As described in greater detail above, some implementations described herein provide a method. The method includes forming, in a first semiconductor die, an optical transceiver, a waveguide coupled with the optical transceiver, and a plurality of grating couplers coupled with the waveguide. The method includes forming, in a second semiconductor die, one or more ARC layers. The method includes bonding the first semiconductor die and the second semiconductor die to form a semiconductor photonics device, where the one or more ARC layers are located over at least a subset of the plurality of grating couplers after the first semiconductor die and the second semiconductor die are bonded. The method includes forming, after bonding the first semiconductor die and the second semiconductor die, one or more micro lenses above the one or more ARC layers.

As used herein, “satisfying a threshold” may, depending on the context, refer to a value being greater than the threshold, greater than or equal to the threshold, less than the threshold, less than or equal to the threshold, equal to the threshold, not equal to the threshold, or the like.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming, in a first semiconductor die:
an optical transceiver,
a waveguide coupled with the optical transceiver, and
a plurality of grating couplers coupled with the waveguide;
forming, in a second semiconductor die, one or more anti-reflective coating (ARC) layers;
bonding the first semiconductor die and the second semiconductor die, wherein the one or more ARC layers are located over at least a subset of the plurality of grating couplers after the first semiconductor die and the second semiconductor die are bonded; and
forming, after bonding the first semiconductor die and the second semiconductor die, one or more micro lenses above the one or more ARC layers.

2. The method of claim 1, further comprising:
forming, in the second semiconductor die, a grating structure above the one or more ARC layers.

3. The method of claim 2, wherein forming the one or more micro lenses comprises:
forming the one or more micro lenses above the grating structure.

4. The method of claim 2, wherein the grating structure is located above one of the plurality of grating couplers.

5. The method of claim 1, further comprising:
forming, in the second semiconductor die, a reflector layer,
wherein forming the one or more ARC layers comprises:
forming the one or more ARC layers above the reflector layer.

6. The method of claim 5, wherein a first portion of the one or more ARC layers is located on the reflector layer; and wherein a second portion of the one or more ARC layers extends laterally outward from the reflector layer.

7. The method of claim 1, further comprising:
forming, in the second semiconductor die, one or more color filter layers over the one or more ARC layers.

8. A method, comprising:
forming, in a first semiconductor die:
an optical transceiver,
a waveguide coupled with the optical transceiver, and
a plurality of grating couplers coupled with the waveguide;
forming, in a second semiconductor die:
a plurality of color filter layers, and
an anti-reflective coating (ARC) layer;
bonding the first semiconductor die and the second semiconductor die,
wherein each color filter layer of the plurality of color filter layers is located above a respective one of the plurality of grating couplers, and the ARC layer is located above the plurality of color filter layers; and
forming, after bonding the first semiconductor die and the second semiconductor die, a micro lens above one or more of the color filter layers.

9. The method of claim 8, wherein the micro lens is formed to span the plurality of color filter layers.

10. The method of claim 8, wherein the micro lens is formed over only a first color filter layer of the plurality of color filter layers; and
wherein the method further comprises forming a reflector layer in the second semiconductor die over a second color filter layer of the plurality of color filter layers.

11. The method of claim 10, wherein the ARC layer is formed between the reflector layer and the second color filter layer.

12. The method of claim 8, wherein the plurality of color filter layers comprises:
a first color filter layer configured to permit transmission of a first wavelength range of incident light, and
a second color filter layer configured to permit transmission of a second wavelength range of the incident light, wherein the first wavelength range is different from the second wavelength range.

13. The method of claim 8, wherein forming the plurality of color filter layers comprises:
forming a first color filter material on the ARC layer; and
forming a second color filter material on the ARC layer and adjacent to the first color filter material.

14. The method of claim 8, wherein at least one of the optical transceiver, the waveguide, or the plurality of grating couplers are formed in a first semiconductor substrate of the first semiconductor die; and
wherein at least one of the plurality of color filter layers, the ARC layer, are the micro lens are formed in or on a second semiconductor substrate of the second semiconductor die.

15. A method, comprising:
forming, in a first semiconductor die:
an optical transceiver,
a waveguide coupled with the optical transceiver,
a plurality of grating couplers coupled with the waveguide, and
one or more first bonding pads electrically coupled with the optical transceiver;
forming, in a second semiconductor die:
a layer stack,
one or more anti-reflective coating (ARC) layers on the layer stack, and
one or more second bonding pads;
bonding the first semiconductor die to the second semiconductor die; and
forming, after the bonding, one or more micro lenses in a backside surface of a semiconductor substrate of the second semiconductor die.

16. The method of claim 15, further comprising:
forming a metal-to-metal bond between the one or more first bonding pads and the one or more second bonding pads.

17. The method of claim 15, further comprising:
forming a dielectric-to-dielectric bond between a first dielectric layer of the first semiconductor die and a second dielectric layer of the second semiconductor die.

18. The method of claim 15, further comprising forming, in the first semiconductor die, one or more metallization layers in a first dielectric layer of a device region above a first semiconductor substrate, wherein the optical transceiver is coupled with the one or more metallization layers.

19. The method of claim 15, further comprising performing backside processing on the first semiconductor die after bonding the first semiconductor die and the second semiconductor die.

20. The method of claim 15, wherein the layer stack of the second semiconductor die comprises an adhesion layer, a passivation layer, a glue layer, or a dielectric layer, and wherein the one or more ARC layers are formed in an oxide fill region of the second semiconductor die under the layer stack.
